(19) United States
(12) Patent Application Publication
(10) Pub. No.: US 2025/0191883 A1
(43) Pub. Date: Jun. 12, 2025

(54) PLASMA PROCESSING APPARATUS, RF SYSTEM, AND RF CONTROL METHOD

(71) Applicant: Tokyo Electron Limited, Tokyo (JP)

(72) Inventor: Ryuta HIGUCHI, Miyagi (JP)

(73) Assignee: Tokyo Electron Limited, Tokyo (JP)

(21) Appl. No.: 19/056,788

(22) Filed: Feb. 19, 2025

Related U.S. Application Data
(63) Continuation of application No. PCT/JP2023/028839, filed on Aug. 8, 2023.

(30) Foreign Application Priority Data
Aug. 22, 2022 (JP) 2022-131591

(51) Int. Cl. H01J 37/32

(52) U.S. Cl. CPC H01J 37/32165; H01J 37/3211; H01J 37/32183; H01J 37/32669; H01J 2237/24564; H01J 2237/334

(57) ABSTRACT

A controller of a plasma processing apparatus is configured to execute (a1) acquiring a first parameter at an input terminal and/or an output terminal of a first matching circuit, (a2) acquiring a second parameter at an input terminal and/or an output terminal of a second matching circuit, and b) performing a first control operation and a second control operation sequentially and repeatedly. The first control operation sequentially performs tuning of a power level of a first RF signal, a frequency of the first RF signal, and a first variable element in the first matching circuit based on the first parameter acquired in the (a1). The second control operation sequentially performs tuning of a power level of a second RF signal, a frequency of the second RF signal, and a second variable element in the second matching circuit based on the second parameter acquired in the (a2).

### CROSS-REFERENCE TO RELATED APPLICATIONS

This application is a continuation application of International Application No. PCT/JP2023/028839, filed on Aug. 8, 2023, which claims the benefit of priority of the prior Japanese Patent Application No. 2022-131591, filed on Aug. 22, 2022, the entire contents of each are incorporated herein by reference.

### FIELD

Various aspects and exemplary embodiments of the present invention relate to a plasma processing apparatus, a radio frequency (RF) system, and an RF control method.

### BACKGROUND

The following Japanese Laid-open Patent Publication No. 2019-71270 discloses that “A plasma processing apparatus includes a chamber, a power supply unit, a matching circuit, a first calculation unit, and a control circuit. The chamber has a space therein and performs processing on a workpiece carried into the space by plasma generated in the space. The power supply unit supplies radio frequency power for generating the plasma in the chamber. The matching circuit matches an impedance between the plasma in the chamber and the power supply unit. The first calculation unit calculates the impedance of the plasma in the chamber. The control circuit controls a frequency of the radio frequency power supplied into the chamber, a magnitude of the radio frequency power, and an impedance of the matching circuit based on the impedance calculated by the first calculation unit. In addition, the first calculation unit and the control circuit are provided on one substrate”.

The present disclosure provides a plasma processing apparatus, a radio frequency (RF) system, and an RF control method capable of more stably maintaining plasma in processing using the plasma.

### SUMMARY

According to an aspect of an embodiment, a plasma processing apparatus includes a plasma processing chamber, a substrate support, an antenna, a first radio frequency (RF) generator, a first matching circuit, a plurality of first sensors, a second RF generator, a second matching circuit, a plurality of second sensors, and a controller. The substrate support is disposed in the plasma processing chamber and including an electrode. The antenna is disposed above the plasma processing chamber. The first RF generator is configured to generate a first RF signal having a first frequency. The first matching circuit includes a first variable element and has a first input terminal and a first output terminal. The first input terminal is coupled to the first RF generator. The first output terminal is coupled to the antenna. The plurality of first sensors are configured to detect at least four first parameters at the first input terminal and/or the first output terminal. The at least four first parameters are associated with the first RF signal. The second RF generator is configured to generate a second RF signal having a second frequency. The second matching circuit includes a second variable element and has a second input terminal and a second output terminal. The second input terminal is coupled to the second RF generator. The second output terminal is coupled to the electrode. The plurality of second sensors are configured to detect at least four second parameters at the second input terminal and/or the second output terminal. The at least four second parameters is associated with the second RF signal. The controller is configured to execute: (a1) acquiring the at least four first parameters simultaneously and repeatedly; (a2) acquiring the at least four second parameters simultaneously and repeatedly; and (b) performing a first control operation and a second control operation sequentially and repeatedly. The first control operation sequentially performs tuning of a power level of the first RF signal in the first RF generator, tuning of a frequency of the first RF signal in the first RF generator, and tuning of the first variable element in the first matching circuit based on the at least four first parameters simultaneously acquired in the (a1). The second control operation sequentially performs tuning of a power level of the second RF signal in the second RF generator, tuning of a frequency of the second RF signal in the second RF generator, and tuning of the second variable element in the second matching circuit based on the at least four second parameters simultaneously acquired in the (a2).

### BRIEF DESCRIPTION OF DRAWINGS

FIG. 1 is a diagram illustrating an example of a configuration of a plasma processing system;

FIG. 2 is a diagram illustrating an example of an inductively coupled plasma processing apparatus;

FIG. 3 is a diagram illustrating an example of a detailed configuration of a power supply;

FIG. 4 is a diagram illustrating an example of a radio frequency (RF) generation unit;

FIG. 5 is a timing chart illustrating an example of detection and control timings;

FIG. 6 is a timing chart illustrating another example of the detection and control timings;

FIG. 7 is a timing chart illustrating still another example of the detection and control timings;

FIG. 8 is a flowchart illustrating an example of a plasma processing method;

FIG. 9A is a diagram illustrating another example of arrangement of sensors;

FIG. 9B is a diagram illustrating another example of the arrangement of the sensors;

FIG. 9C is a diagram illustrating another example of the arrangement of the sensors;

FIG. 10 is a diagram illustrating another example of the plasma processing apparatus;

FIG. 11 is a top view illustrating an example of connection between the power supply and a plurality of electromagnets; and

FIG. 12 is a diagram illustrating another example of the detailed configuration of the power supply.

### DESCRIPTION OF EMBODIMENTS

Hereinafter, exemplary embodiments of a plasma processing apparatus, a radio frequency (RF) system, and an RF control method that are disclosed will be described in detail with reference to the drawings. Note that a plasma processing apparatus, a RF system, and an RF control method that are disclosed are not limited by the following exemplary embodiments.

In each of the exemplary embodiments exemplified below, “coupling” means connection in a state in which signal transmission is possible. In addition, “at least one of A, B, and C” means any one of (A), (B), (C), (A and B), (B and C), (C and A), and (A, B, and C).

Meanwhile, in a process such as etching using plasma, RF signals of a plurality of different frequencies may be used. In this case, it is conceivable to generate a plurality of RF signals by using a plurality of signal generators. However, when the signal generators control powers and frequencies of the RF signals independently of each other, control timings may overlap each other. When the control timings overlap each other, timings of transient changes of the RF signals by the control overlap each other, and the plasma may become unstable due to disappearance of the plasma, flowing of an excessive amount of current, or the like. When the plasma becomes unstable, quality of a semiconductor substrate after plasma processing may be lower than a desired quality.

Therefore, the present disclosure provides a technology capable of more stably maintaining plasma in processing using the plasma.

### Configuration Example of Plasma Processing System

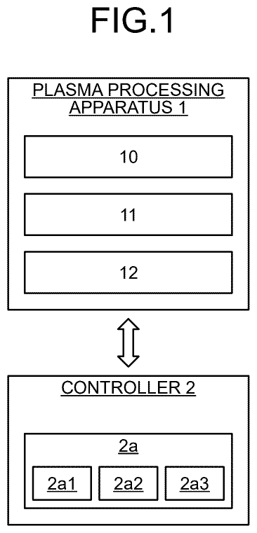

FIG. 1 is a diagram illustrating an example of a configuration of the plasma processing system. In one exemplary embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. In addition, the plasma processing chamber 10 has at least one gas supply port for supplying at least one process gas to the plasma processing space and at least one gas discharge port for discharging the gas from the plasma processing space. The gas supply port is connected to a gas supply 20 described below, and the gas discharge port is connected to an exhaust system 40 described below. The substrate support 11 is disposed in the plasma processing space and has a substrate support surface for supporting the substrate.

The plasma generator 12 is configured to generate a plasma from at least one process gas supplied into the plasma processing space. The plasma formed in the plasma processing space may be capacitively coupled plasma (CCP), inductively coupled plasma (ICP), electron-cyclotron-resonance plasma (ECR plasma), helicon wave plasma (HWP), surface wave plasma (SWP), or the like. In addition, various types of plasma generators including an alternating current (AC) plasma generator and a direct current (DC) plasma generator may be used. In one exemplary embodiment, an AC signal (AC power) used in the AC plasma generator has a signal of a frequency in a range of 100 kHz to 10 GHZ. Therefore, the AC signal includes a radio frequency (RF) signal and a microwave signal. In one exemplary embodiment, the RF signal has a frequency in a range of 100 kHz to 150 MHZ.

The controller 2 processes computer-executable instructions that cause the plasma processing apparatus 1 to perform various processes described in the present disclosure. The controller 2 can be configured to control each element of the plasma processing apparatus 1 so as to perform various processes described herein. In one exemplary embodiment, a part of or the entire controller 2 may be included in the plasma processing apparatus 1. The controller 2 may include a processing unit 2a1, a storage 2a2, and a communication interface 2a3. The controller 2 is implemented by, for example, a computer 2a. The processing unit 2a1 can be configured to perform various control operations by reading a program from the storage 2a2 and executing the read program. The program may be stored in the storage 2a2 in advance, or may be acquired via a medium when necessary. The acquired program is stored in the storage 2a2, and is read from the storage 2a2 and executed by the processing unit 2a1. The medium may be various storage media readable by the computer 2a, or may be a communication line connected to the communication interface 2a3. The processing unit 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

### Configuration Example of Plasma Processing Apparatus 1

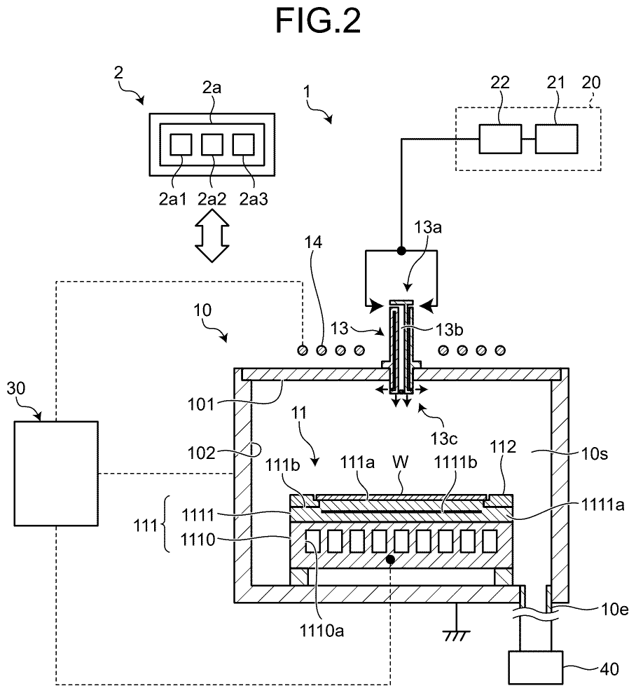

Hereinafter, a configuration example of an inductively coupled plasma processing apparatus as an example of the plasma processing apparatus 1 will be described. FIG. 2 is a diagram illustrating an example of the inductively coupled plasma processing apparatus 1.

The inductively coupled plasma processing apparatus 1 includes the plasma processing chamber 10, the gas supply 20, a power supply 30, and the exhaust system 40. The plasma processing chamber 10 includes a dielectric window 101. The plasma processing apparatus 1 includes the substrate support 11, a gas introduction unit, and an antenna 14. The substrate support 11 is disposed in the plasma processing chamber 10. The antenna 14 is disposed on or above the plasma processing chamber 10 (that is, on or above the dielectric window 101). The plasma processing chamber 10 has a plasma processing space 10s defined by the dielectric window 101, a side wall 102 of the plasma processing chamber 10, and the substrate support 11. The plasma processing chamber 10 is grounded.

The substrate support 11 includes a body 111 and a ring assembly 112. The body 111 has a central region 111a for supporting a substrate W and an annular region 111b for supporting the ring assembly 112. A wafer is an example of the substrate W. The annular region 111b of the body 111 surrounds the central region 111a of the body 111 in plan view. The substrate W is disposed on the central region 111a of the body 111, and the ring assembly 112 is disposed on the annular region 111b of the body 111 so as to surround the substrate W on the central region 111a of the body 111. Therefore, the central region 111a is also referred to as a substrate support surface for supporting the substrate W, and the annular region 111b is also referred to as a ring support surface for supporting the ring assembly 112.

In one exemplary embodiment, the body 111 includes a base 1110 and an electrostatic chuck 1111. The base 1110 includes a conductive member. The conductive member of the base 1110 can function as a bias electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has a central region 111a. In one exemplary embodiment, the ceramic member 1111a also has the annular region 111b. Another member surrounding the electrostatic chuck 1111, such as an annular electrostatic chuck or an annular insulating member, may have the annular region 111b. In this case, the ring assembly 112 may be disposed on the annular electrostatic chuck or the annular insulating member, or may be disposed on both the electrostatic chuck 1111 and the annular insulating member. In addition, at least one RF/DC electrode coupled to an RF generator and/or a DC signal generator described below may be disposed in the ceramic member 1111a. In this case, at least one RF/DC electrode functions as a bias electrode. The conductive member of the base 1110 and at least one RF/DC electrode may function as a plurality of bias electrodes. In addition, the electrostatic electrode 1111b may function as a bias electrode. Therefore, the substrate support 11 includes at least one bias electrode.

The ring assembly 112 includes one or more annular members. In one exemplary embodiment, the one or more annular members include one or more edge rings and at least one cover ring. The edge ring is formed of a conductive material or an insulating material, and the cover ring is formed of an insulating material.

The substrate support 11 may include a temperature adjustment module configured to adjust at least one of temperatures of the electrostatic chuck 1111, the ring assembly 112, and the substrate to a target temperature. The temperature adjustment module may include a heater, a heat transfer medium, a channel 1110a, or a combination thereof. Heat transfer fluid such as brine or gas flows through the channel 1110a. In one exemplary embodiment, the channel 1110a is formed in the base 1110 and one or more heaters are disposed in the ceramic member 1111a of the electrostatic chuck 1111. Further, the substrate support 11 may include a heat transfer gas supply configured to supply heat transfer gas to a gap between a reverse face of the substrate W and the central region 111a.

The gas introduction unit is configured to introduce at least one process gas from the gas supply 20 into the plasma processing space 10s. In one exemplary embodiment, the gas introduction unit includes a center gas injector (CGI) 13. The center gas injector 13 is disposed above the substrate support 11 and is attached to a central opening formed in the dielectric window 101. The center gas injector 13 has at least one gas supply port 13a, at least one gas channel 13b, and at least one gas introduction port 13c. The process gas supplied to the gas supply port 13a passes through the gas channel 13b and is introduced into the plasma processing space 10s from the gas introduction port 13c. The gas introduction unit may include one or more side gas injectors (SGI) attached to one or more openings formed in the side wall 102 in addition to or instead of the center gas injector 13.

The gas supply 20 may include at least one gas source 21 and at least one flow controller 22. In one exemplary embodiment, the gas supply 20 is configured to supply at least one process gas from each corresponding gas source 21 to the gas introduction unit via each corresponding flow controller 22. Each flow controller 22 may include, for example, a mass flow controller or a pressure control type flow controller. In addition, the gas supply 20 may include at least one flow modulation device that modulates or pulses a flow volume of the at least one process gas.

The power supply 30 includes the RF generator coupled to the plasma processing chamber 10 via at least one impedance matching circuit. The RF generator is configured to supply at least one RF signal (RF power) to at least one bias electrode and the antenna 14. As a result, the plasma is formed from at least one process gas supplied to the plasma processing space 10s. Therefore, the RF generator can function as at least a part of the plasma generator 12. In addition, as a bias RF signal is supplied to at least one bias electrode, a bias potential is generated in the substrate W, and ions in the formed plasma can be drawn into the substrate W. A detailed configuration example of the power supply 30 is described below.

The antenna 14 includes one or more coils. In one exemplary embodiment, the antenna 14 may include an outer coil and an inner coil arranged coaxially. In this case, the RF generator may be connected to both the outer coil and the inner coil, or may be connected to one of the outer coil and the inner coil. In the former case, the same RF generator may be connected to both the outer coil and the inner coil, and separate RF generators may be separately connected to the outer coil and the inner coil.

The exhaust system 40 can be connected to a gas discharge port 10e provided, for example, at a bottom portion of the plasma processing chamber 10. The exhaust system 40 may include a pressure regulating valve and a vacuum pump. A pressure in the plasma processing space 10s is adjusted by the pressure regulating valve. The vacuum pump may include a turbomolecular pump, a dry pump, or a combination thereof.

### Detailed Configuration Example of Power Supply 30

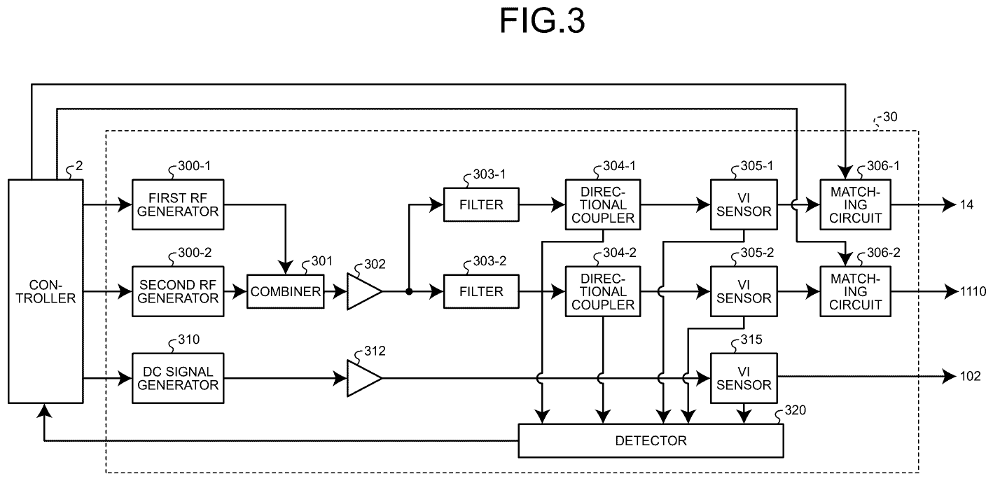

FIG. 3 is a diagram illustrating an example of a detailed configuration of the power supply 30. The power supply 30 in the present exemplary embodiment includes a first RF generator 300-1, a second RF generator 300-2, a combiner 301, an amplifier 302, a filter 303-1, a filter 303-2, a directional coupler 304-1, and a directional coupler 304-2. In addition, the power supply 30 in the present exemplary embodiment includes a VI sensor 305-1, a VI sensor 305-2, a matching circuit 306-1, a matching circuit 306-2, a DC signal generator 310, an amplifier 312, a VI sensor 315, and a detector 320. Hereinafter, the first RF generator 300-1 and the second RF generator 300-2 will be collectively referred to as an RF generator 300 without distinction, and the filter 303-1 and the filter 303-2 will be collectively referred to as a filter 303 without distinction. Hereinafter, the directional coupler 304-1 and the directional coupler 304-2 will be collectively referred to as a directional coupler 304 without distinction. In the following description, the VI sensor 305-1 and the VI sensor 305-2 will be collectively referred to as a VI sensor 305 without distinction, and the matching circuit 306-1 and the matching circuit 306-2 will be collectively referred to as a matching circuit 306 without distinction. The controller 2 and the power supply 30 are an example of an RF system.

The first RF generator 300-1 generates a first RF signal including a signal of a first frequency. In one exemplary embodiment, the first RF generator 300-1 is configured to generate the first RF signal having the first frequency. The first RF signal is an example of a source RF signal. In the present exemplary embodiment, the first frequency is, for example, a frequency within a range of 10 MHz to 150 MHz. In the present exemplary embodiment, the first RF generator 300-1 generates the source RF signal including one or more signals of different frequencies including the signal of the first frequency, and the generated source RF signal is supplied to the antenna 14.

The second RF generator 300-2 generates a second RF signal including a signal of a second frequency. In one exemplary embodiment, the second RF generator 300-2 is configured to generate the second RF signal having the second frequency. The second RF signal is an example of the bias RF signal (bias RF power). The second frequency may be the same as or different from the first frequency. In addition, the second frequency may be lower than the first frequency. In the present exemplary embodiment, the second frequency is, for example, a frequency within a range of 100 kHz to 60 MHz. In the present exemplary embodiment, the second RF generator 300-2 generates the bias RF signal including one or more signals of different frequencies including the signal of the second frequency, and the generated bias RF signal is supplied to the bias electrode of the base 1110. At least one of the source RF signal and the bias RF signal may be pulsed.

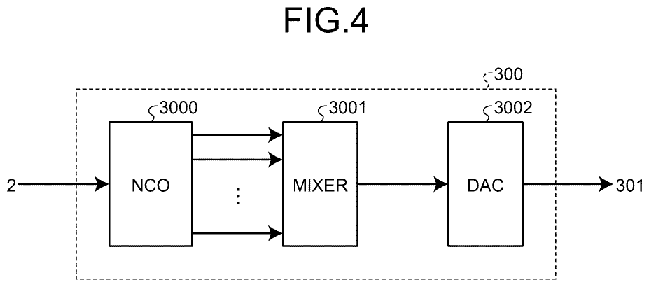

The first RF generator 300-1 and the second RF generator 300-2 are implemented by, for example, the RF generator 300 as illustrated in FIG. 4. The RF generator 300 includes a numerically controlled oscillator (NCO) 3000, a mixer 3001, and a digital analog converter (DAC) 3002. The NCO 3000 of the first RF generator 300-1 generates the first RF signal including signals of one or more frequencies including the signal of the first frequency. The NCO 3000 of the second RF generator 300-2 generates the second RF signal including signals of one or more frequencies including the signal of the second frequency. The mixer 3001 combines the plurality of RF signals generated by the NCO 3000. When an RF signal of a single frequency is output from the NCO 3000, the mixer 3001 passes the RF signal output from the NCO 3000 without combining the RF signal. The DAC 3002 converts the RF signal output from the mixer 3001 from a digital signal to an analog signal.

The NCO 3000 generates an RF signal of one or more frequencies included in a frequency band of several hundred kHz to several MHz including the signal of the first frequency or the second frequency, for example. For example, a frequency of an RF signal supplied into the plasma processing space 10s when the plasma is ignited may be different from a frequency of an RF signal supplied into the plasma processing space 10s in order to stably maintain the plasma after the plasma is ignited. The NCO 3000 can achieve both reliable ignition and stable maintenance of the plasma by generating a plurality of RF signals including the signals of these frequencies.

Returning to FIG. 3, the description will be continued. The combiner 301 is coupled to an output terminal of the first RF generator 300-1 and an output terminal of the second RF generator 300-2, and combines the first RF signal generated by the first RF generator 300-1 and the second RF signal generated by the second RF generator 300-2. The combiner 301 is an example of an RF signal combiner. The amplifier 302 is coupled to an output terminal of the combiner 301 and amplifies the RF signal combined by the combiner 301. The amplifier 302 is a broadband amplifier capable of amplifying a signal in a frequency band including the frequency band of the first RF signal generated by the first RF generator 300-1 and the frequency band of the second RF signal generated by the second RF generator 300-2.

The filter 303-1 is coupled to an output terminal of the amplifier 302 and passes a frequency component included in the first RF signal in the signal amplified by the amplifier 302. The filter 303-2 is coupled to the output terminal of the amplifier 302 and passes a frequency component included in the second RF signal in the signal amplified by the amplifier 302. The filter 303-1 is an example of a first filter, and the filter 303-2 is an example of a second filter.

The directional coupler 304-1 and the VI sensor 305-1 detect a plurality of first parameters associated with the first RF signal in a signal line between the first RF generator 300-1 and matching circuit 306-1, through which the first RF signal propagates. The directional coupler 304-1 and the VI sensor 305-1 are examples of first sensors. The directional coupler 304-2 and the VI sensor 305-2 detect a plurality of pieces of second parameter information associated with the second RF signal in a signal line between the second RF generator 300-2 and the matching circuit 306-2, through which the second RF signal propagates. The directional coupler 304-2 and the VI sensor 305-2 are examples of second sensors. In one exemplary embodiment, the plurality (at least two) of first sensors are configured to detect at least four first parameters at a first input terminal and/or a first output terminal of the matching circuit 306-1. The at least four first parameters are associated with the first RF signal. In one exemplary embodiment, the plurality of first sensors are configured to detect at least four first parameters at the first input terminal of the matching circuit 306-1. The at least four first parameters are associated with the first RF signal. In one exemplary embodiment, each of the at least four first parameters is selected from the group consisting of power, voltage, and current for a traveling wave of the first RF signal, and power, voltage, and current for a reflected wave of the first RF signal. In one exemplary embodiment, the plurality of (at least two) second sensors are configured to detect at least four second parameters at a second input terminal and/or a second output terminal of the matching circuit 306-2. In one exemplary embodiment, the plurality of second sensors are configured to detect at least four second parameters at the second input terminal of the matching circuit 306-2. The at least four second parameters are associated with the second RF signal. In one exemplary embodiment, each of the at least four second parameters is selected from the group consisting of power, voltage, and current for a traveling wave of the second RF signal, and power, voltage, and current for a reflected wave of the second RF signal.

The first parameter detected by the directional coupler 304-1 includes, for example, information regarding a peak value and a phase of the power of each of the traveling wave and the reflected wave in the first RF signal. The first parameter detected by the VI sensor 305-1 includes, for example, information regarding magnitudes of the voltage and the current and a phase of the first RF signal at the input terminal of the matching circuit 306-1. The input terminal of the matching circuit 306-1 is an example of a first input terminal, and the output terminal of the matching circuit 306-1 is an example of a first output terminal.

The second parameter detected by the directional coupler 304-2 includes, for example, information regarding a peak value and a phase of the power of each of the traveling wave and the reflected wave in the second RF signal. The second parameter detected by the VI sensor 305-2 includes, for example, information regarding magnitudes of the voltage and the current and a phase of the second RF signal at the input terminal of the matching circuit 306-2. The input terminal of the matching circuit 306-2 is an example of a second input terminal, and the output terminal of the matching circuit 306-2 is an example of a second output terminal.

The matching circuit 306-1 is provided in a signal line through which the first RF signal generated by the first RF generator 300-1 and supplied to the antenna 14 propagates. The matching circuit 306-2 is provided in a signal line through which the second RF signal generated by the second RF generator 300-2 and supplied to the bias electrode of the base 1110 propagates. The matching circuit 306-1 and the matching circuit 306-2 include reactance elements whose reactance values are controlled by an actuator. The actuator is controlled by the controller 2. Therefore, the reactance elements of the matching circuit 306-1 and the matching circuit 306-2 are controlled by the controller 2. The matching circuit 306-1 is an example of a first matching circuit, and the matching circuit 306-2 is an example of a second matching circuit. The reactance element included in the matching circuit 306-1 is an example of a first variable element, and the reactance element included in the matching circuit 306-2 is an example of a second variable element. In one exemplary embodiment, the matching circuit 306-1 includes the first variable element and has the first input terminal and the first output terminal. The first input terminal is coupled to the first RF generator 300-1, and the first output terminal is coupled to the antenna 14. In one exemplary embodiment, the variable element is a variable capacitor or a variable inductor. In one exemplary embodiment, the matching circuit 306-2 includes the second variable element and has the second input terminal and the second output terminal. The second input terminal is coupled to the second RF generator 300-2 and the second output terminal is coupled to the bias electrode in the substrate support 11.

By controlling the reactance element of the matching circuit 306-1, an output impedance of the power supply 30 with respect to the antenna 14 is controlled, and a matching state between the output impedance of the power supply 30 and an input impedance of the antenna 14 changes. As a result, first RF power supplied from the power supply 30 to the plasma via the antenna 14 changes, and a state of the plasma in the plasma processing chamber 10 changes. Similarly, by controlling the reactance element of the matching circuit 306-2, an output impedance of the power supply 30 with respect to the bias electrode of the base 1110 is controlled, and a matching state between the output impedance of the power supply 30 and an input impedance of the bias electrode of the base 1110 changes. As a result, second RF power supplied from the power supply 30 to the plasma via the bias electrode of the base 1110 changes, and the state of the plasma in the plasma processing chamber 10 changes.

The DC signal generator 310 generates a DC signal having a frequency lower than the frequencies of the first RF signal and the second RF signal. In the present exemplary embodiment, the DC signal generated by the DC signal generator 310 is applied to the side wall 102 of the plasma processing chamber 10. The DC signal applied to the side wall 102 changes the state of the plasma in the plasma processing chamber 10. The DC signal generated by the DC signal generator 310 may be applied to other members in the plasma processing chamber 10, such as the bias electrode of the base 1110 and a Faraday shield (not illustrated). In the present exemplary embodiment, the DC signal generator 310 is an example of a voltage pulse generator, and an output terminal of the DC signal generator 310 is an example of a third output terminal.

Furthermore, in the present exemplary embodiment, the DC signal generated by the DC signal generator 310 is, for example, a pulse signal with a period of several hundred kHz. A voltage pulse may have a pulse waveform of a rectangle, a trapezoid, a triangle, or a combination thereof. In one exemplary embodiment, a waveform generator for generating a sequence of the voltage pulses from the DC signal is connected between the DC signal generator 310 and at least one bias electrode. Therefore, the DC signal generator 310 and the waveform generator form the voltage pulse generator. The voltage pulse may have a positive polarity or a negative polarity. The sequence of the voltage pulses may also include one or more positive voltage pulses and one or more negative voltage pulses within one period.

The amplifier 312 is coupled to the output terminal of the DC signal generator 310 and amplifies the DC signal generated by the DC signal generator 310. The VI sensor 315 detects a plurality of third parameters associated with the DC signal in a signal line between the DC signal generator 310 and a member (the side wall 102 in the present exemplary embodiment) in the plasma processing chamber 10, through which the DC signal propagates. The third parameter detected by the VI sensor 315 includes, for example, information regarding the magnitudes of the voltage and the current and a phase of the DC signal. The VI sensor 315 is an example of a third sensor.

The detector 320 acquires the first parameter detected by the directional coupler 304-1 and the VI sensor 305-1, the second parameter detected by the directional coupler 304-2 and the VI sensor 305-2, and the third parameter detected by the VI sensor 315. Then, the detector 320 outputs the acquired first parameter, second parameter, and third parameter to the controller 2.

The controller 2 controls the magnitude of the power and the frequency of the first RF signal and controls the reactance element in the matching circuit 306-1 based on the first parameter output from the detector 320. In addition, the controller 2 controls the magnitude of the power and the frequency of the second RF signal and controls the reactance element in the matching circuit 306-2 based on the second parameter output from the detector 320. In addition, the controller 2 controls a state of the DC signal including the magnitude of the voltage of the DC signal based on the third parameter output from the detector 320.

The controller 2 may control the magnitude of the power and the frequency of the first RF signal and control the reactance element in the matching circuit 306-1 by further using at least one of the detected second parameter and third parameter. Furthermore, the controller 2 may control the magnitude of the power and frequency of the second RF signal and control the reactance element in the matching circuit 306-2 by further using at least one of the detected first parameter and third parameter. Further, the controller 2 may control the state of the DC signal by further using at least one of the detected first parameter and second parameter.

### Detection and Control Timings

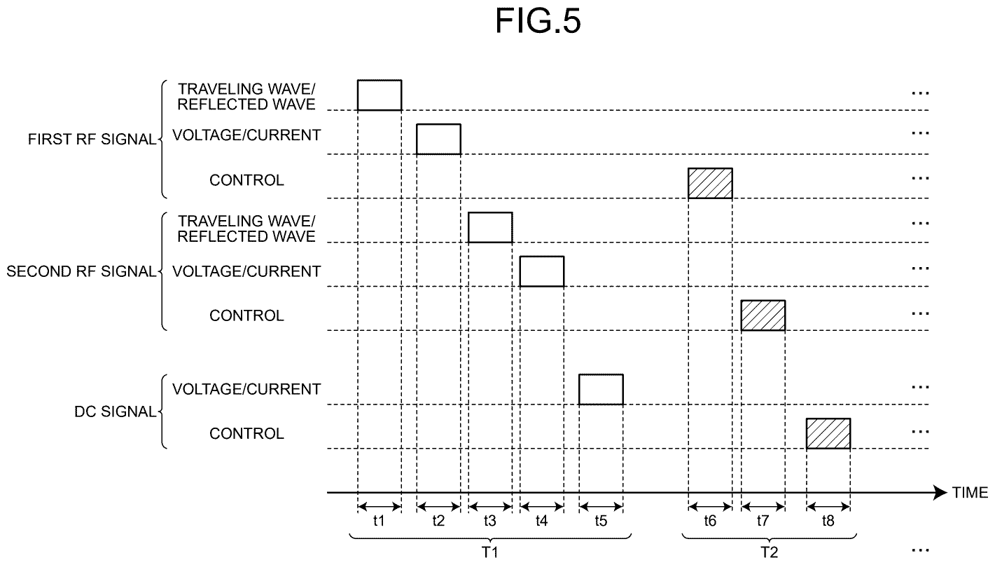

FIG. 5 is a timing chart illustrating an example of detection and control timings. In FIG. 5, an unhatched square indicates a timing at which a detection value acquired by the detector 320 is detected, and a hatched square indicates a timing at which control is performed.

For example, as illustrated in FIG. 5, the detector 320 acquires detection values of the traveling wave and the reflected wave of the first RF signal detected at a timing t1 by the directional coupler 304-1. In addition, the detector 320 acquires detection values of the voltage and the current of the first RF signal detected at a timing t2 by the VI sensor 305-1. In addition, the detector 320 acquires detection values of the traveling wave and the reflected wave of the second RF signal detected at a timing t3 by the directional coupler 304-2. In addition, the detector 320 acquires detection values of the voltage and the current of the second RF signal detected at a timing t4 by the VI sensor 305-2. In addition, the detector 320 acquires detection values of the voltage and the current of the DC signal detected at a timing t5 by the VI sensor 315.

Furthermore, for example, as illustrated in FIG. 5, the controller 2 controls the magnitude of the power and the frequency of the first RF signal and controls the reactance element in the matching circuit 306-1 at a timing t6 based on the first parameters detected at the timings t1 and t2. In addition, the controller 2 controls the magnitude of the power and the frequency of the second RF signal and controls the reactance element in the matching circuit 306-2 at a timing t7 based on the second parameters detected at the timings t3 and t4. In addition, the controller 2 controls the state of the DC signal at a timing t8 based on the third parameter detected at the timing t5.

The controller 2 detects each signal in a period T1 and controls the state of each signal in a period T2. The period T1 and the period T2 are alternately repeated.

Here, when the detection and the control of the first RF signal and the detection and the control of the second RF signal are independently performed, a timing at which the control of one RF signal is performed and a timing at which the state of the other RF signal is detected may overlap each other. When the timing at which the control of one RF signal is performed and the timing at which the state of the other RF signal is detected overlap each other, the state of the other RF signal may be detected with respect to the state of the plasma that has transiently changed by the control of the one RF signal. In such a case, the transient state of the other RF signal may be detected, and desired control may not be performed on the other RF signal. As a result, the plasma may be unstable due to disappearance of the plasma, flowing of an excessive amount of current, or the like. When the plasma becomes unstable, quality of the substrate after the plasma processing may be lower than a desired quality.

On the other hand, in the present exemplary embodiment, for example, as illustrated in FIG. 5, the period T1 in which each signal is detected is different from the period T2 in which the state of each signal is controlled. As a result, it is possible to avoid overlap between the timing at which the control of one RF signal is performed and the timing at which the state of the other RF signal is detected, and it is possible to stably maintain the plasma.

In addition, when the timing at which the control of one RF signal is performed and the timing at which the control of the other RF signal is performed overlap each other, transient changes of the plasma accompanying the control of the two RF signals overlap each other, and as a result of which the plasma may excessively change. If the plasma excessively changes, the plasma may become unstable.

On the other hand, in the present exemplary embodiment, for example, as illustrated in FIG. 5, the control of each signal is performed at different timings t6 to t8. As a result, it is possible to avoid an excessive change in the plasma accompanying the control of the two RF signals, and it is possible to stably maintain the plasma.

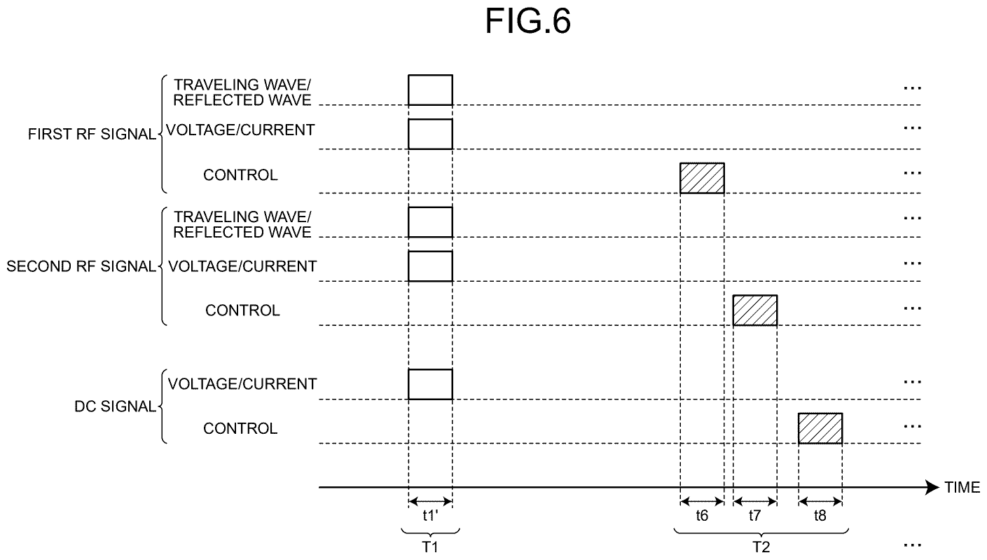

The detection of the state of each signal may be performed at the same timing t1′, for example, as illustrated in FIG. 6. As a result, the period T1 in which the detection of each signal is performed can be shortened, and the detection and the control of each signal can be performed many times in a shorter time. As a result, each signal can be controlled at a higher speed, and the plasma can be maintained more stably.

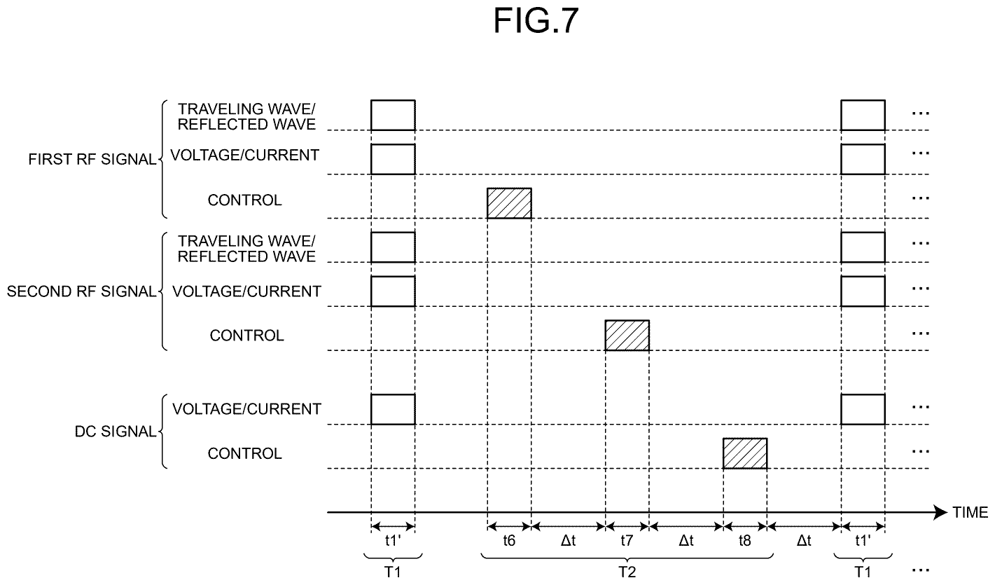

Furthermore, for example, as illustrated in FIG. 7, a period of Δt is preferably provided from the timing t6 to the timing t8 at which the state of each signal is controlled. The period of Δt is, for example, a time required for stabilizing the transient change of the plasma by the signal after the control is performed. In the example of FIG. 7, the same period Δt is provided from the timing t6 to the timing t8 at which the state of each signal is controlled, but lengths of the respective periods Δt may be different from each other. In addition, the length of each period Δt may be changed according to a change in the state of the plasma or the degree of progress of the processing of the substrate.

### Plasma Processing Method

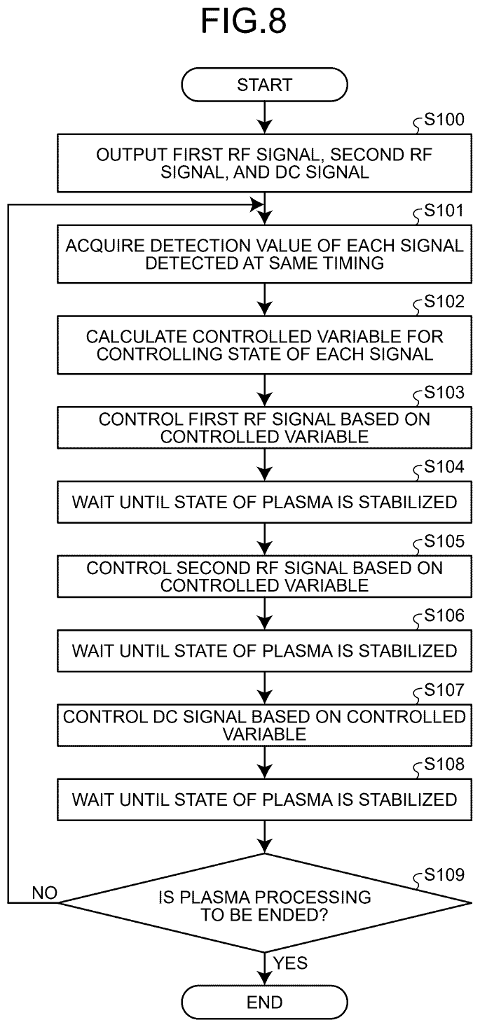

FIG. 8 is a flowchart illustrating an example of a plasma processing method. Processing illustrated in FIG. 8 is implemented by the controller 2 controlling each unit of the plasma processing apparatus 1. In addition, in the plasma processing method illustrated in FIG. 8, the detection and the control of each signal are performed at the timing illustrated in FIG. 7. The plasma processing method illustrated in FIG. 8 is an example of an RF control method.

First, the controller 2 controls the first RF generator 300-1, the second RF generator 300-2, and the DC signal generator 310 to output the first RF signal, the second RF signal, and the DC signal (S100).

Next, the controller 2 controls the detector 320 to acquire the detection value (the first parameter, the second parameter, and the third parameter) of each signal detected at the same timing from the detector 320 (S101). Step S101 is an example of processes (a1), (a2), and (c).

Next, the controller 2 calculates a controlled variable for controlling the state of each signal based on the detection value of each signal acquired from the detector 320 (S102). The controlled variable for controlling the state of each signal includes controlled variables of the power, the voltage, and the frequency of each signal, the reactance element, and the like.

Next, the controller 2 controls the first RF signal based on the controlled variable calculated in step S102 (S103). Step S103 is an example of first control operation and a process (d). The control performed in step S103 includes control of the magnitude of the power and the frequency of the first RF signal and control of the reactance element included in the matching circuit 306-1.

Next, the controller 2 waits until the state of the plasma is stabilized (S104). Step S104 corresponds to the period Δt between the timing t6 and the timing t7 in FIG. 7.

Next, the controller 2 controls the second RF signal based on the controlled variable calculated in step S102 (S105). Step S105 is an example of second control operation and a process (e). The control performed in step S105 includes control of the magnitude of the power and the frequency of the second RF signal and control of the reactance element included in the matching circuit 306-2.

Next, the controller 2 waits until the state of the plasma is stabilized (S106). Step S106 corresponds to the period Δt between the timing t7 and the timing t8 in FIG. 7.

Next, the controller 2 controls the DC signal based on the controlled variable calculated in step S102 (S107). Step S107 is an example of fourth control operation. The control performed in step S107 includes control of the state of the DC signal such as the magnitude of the voltage of the DC signal.

Next, the controller 2 waits until the state of the plasma is stabilized (S108). Step S108 corresponds to the period Δt between the timing t8 and the next timing t1′ in FIG. 7.

Next, the controller 2 judges whether or not to end the plasma processing (S109). When the plasma processing is not to be ended (S109: No), the controller 2 executes the processing shown in step S101 again. On the other hand, when the plasma processing is to be ended (S109: Yes), the controller 2 controls the first RF generator 300-1, the second RF generator 300-2, and the DC signal generator 310 to stop outputting the first RF signal, the second RF signal, and the DC signal. Then, the controller 2 ends the plasma processing method shown in this flowchart.

One exemplary embodiment has been described above. As described above, the plasma processing apparatus 1 according to the present exemplary embodiment includes the plasma processing chamber 10, the substrate support 11, the antenna 14, the first RF generator 300-1, the matching circuit 306-1, the plurality of first sensors, the second RF generator 300-2, the matching circuit 306-2, the plurality of second sensors, and the controller 2. The substrate support 11 is disposed in the plasma processing chamber 10 and includes the bias electrode. The antenna 14 is disposed above the plasma processing chamber 10. The first RF generator 300-1 generates the first RF signal including the signal of the first frequency. The matching circuit 306-1 includes the first variable element and is provided in the signal line through which the first RF signal generated by the first RF generator 300-1 and supplied to the antenna 14 propagates. The plurality of first sensors detect at least four first parameters associated with the first RF signal in the signal line between the first RF generator 300-1 and the matching circuit 306-1, through which the first RF signal propagates. The second RF generator 300-2 generates the second RF signal including the signal of the second frequency different from the first frequency. The matching circuit 306-2 includes the second variable element and is provided in the signal line through which the second RF signal generated by the second RF generator 300-2 and supplied to the bias electrode of the substrate support 11 propagates. The plurality of second sensors detect at least four second parameters associated with the second RF signal in the signal line between the second RF generator 300-2 and the matching circuit 306-2, through which the second RF signal propagates. The controller 2 performs the process (c), the process (d), and the process (e). In the process (c), the first parameter and the second parameter detected by the first sensor and the second sensor are acquired. In the process (d), the control of the magnitude of the power and the first frequency of the first RF signal and the control of the first variable element are performed based on the first parameter acquired by the process (c). In the process (e), the control of the magnitude of the power and the second frequency of the second RF signal and the control of the second variable element are performed based on the second parameter acquired in the process (c). In addition, the detection of the first parameter and the second parameter in the process (c), and the process (d) and the process (e) are performed at different timings. As a result, the plasma can be more stably maintained.

In the above exemplary embodiment, the controller 2 acquires the first parameter and the second parameter detected at the same timing in the process (c). As a result, a time during which each signal is detected can be shortened, and the detection and the control of each signal can be performed many times in a shorter time. As a result, each signal can be controlled at a higher speed, and the plasma can be maintained more stably.

In the above exemplary embodiment, the controller 2 performs the process (d) and the process (e) at different timings. As a result, it is possible to avoid an excessive change in the plasma accompanying the control of the two RF signals, and it is possible to stably maintain the plasma.

In addition, the plasma processing apparatus 1 according to the above exemplary embodiment further includes the DC signal generator 310 and the VI sensor 315. The DC signal generator 310 is coupled to the bias electrode in the substrate support 11 or the member in the plasma processing chamber 10 and generates a signal of a frequency lower than the first frequency and the second frequency. The VI sensor 315 detects the third parameter associated with the signal supplied from the DC signal generator 310 to the bias electrode or the member in the plasma processing chamber 10. In the process (c), the controller 2 acquires the third parameter detected by the third sensor. In addition, the controller 2 performs a process (f) of controlling the state of the signal including the magnitude of the voltage of the signal supplied from the DC signal generator 310 to the bias electrode in the substrate support 11 or the member in the plasma processing chamber 10 based on the third parameter acquired in the process (c). The process (f) is performed at a timing different from that of the detection of the first parameter, the second parameter, and the third parameter in the process (c). As a result, the plasma can be more stably maintained.

In the above exemplary embodiment, the controller 2 acquires the first parameter, the second parameter, and the third parameter detected at the same timing in the process (c). As a result, a time during which each signal is detected can be shortened, and the detection and the control of each signal can be performed many times in a shorter time. As a result, each signal can be controlled at a higher speed, and the plasma can be maintained more stably.

In the above exemplary embodiment, the controller 2 performs the process (d), the process (e), and the process (f) at different timings. As a result, it is possible to avoid an excessive change in the plasma accompanying the control of the plurality of signals, and to stably maintain the plasma.

The plasma processing apparatus 1 according to the above exemplary embodiment further includes the combiner 301, the amplifier 302, the filter 303-1, and the filter 303-2. The combiner 301 is coupled to the output terminal of the first RF generator 300-1 and the output terminal of the second RF generator 300-2, and combines the first RF signal output from the first RF generator 300-1 and the second RF signal output from the second RF generator 300-2. The amplifier 302 is coupled to the output terminal of the combiner 301 and amplifies the signal combined by the combiner 301. The filter 303-1 is coupled to the output terminal of the amplifier 302 and passes the frequency component included in the first RF signal in the signal amplified by the amplifier 302 to the matching circuit 306-1. The filter 303-2 is connected to the output terminal of the amplifier 302, and passes the frequency component included in the second RF signal in the signal amplified by the amplifier 302 to the matching circuit 306-2. As a result, the number of amplifiers 302 can be reduced, and the power supply 30 can be downsized.

Furthermore, in the above exemplary embodiment, the first parameter includes information regarding the traveling wave and the reflected wave in the first RF signal, and information regarding the voltage and the current at the input terminal of the matching circuit 306-1. The second parameter also includes information regarding the traveling wave and the reflected wave in the second RF signal and information regarding the voltage and the current at the input terminal of the matching circuit 306-2. As a result, the state of the plasma generated in the plasma processing space 10s can be accurately monitored through the states of the first RF signal and the second RF signal.

In addition, the above RF system is an RF system coupled to the plasma processing apparatus 1, and includes the first RF generator 300-1, the matching circuit 306-1, the first sensor, the second RF generator 300-2, the matching circuit 306-2, the second sensor, and the controller 2. The first RF generator 300-1 generates the first RF signal including the signal of the first frequency. The matching circuit 306-1 includes the first variable element and is provided in the signal line through which the first RF signal generated by the first RF generator 300-1 and supplied to the member included in the plasma processing apparatus 1 propagates. The first sensor detects the plurality of first parameters associated with the first RF signal in the signal line between the first RF generator 300-1 and the matching circuit 306-1, through which the first RF signal propagates. The second RF generator 300-2 generates the second RF signal including the signal of the second frequency different from the first frequency. The matching circuit 306-2 includes the second variable element and is provided in the signal line through which the second RF signal generated by the second RF generator 300-2 and supplied to the member included in the plasma processing apparatus 1 propagates. The second sensor detects the plurality of second parameters associated with the second RF signal in the signal line between the second RF generator 300-2 and the matching circuit 306-2, through which the second RF signal propagates. The controller 2 performs the process (c), the process (d), and the process (e). In the process (c), the first parameter and the second parameter detected by the first sensor and the second sensor are acquired. In the process (d), the control of the magnitude of the power and the first frequency of the first RF signal and the control of the first variable element are performed based on the first parameter acquired by the process (c). In the process (e), the control of the magnitude of the power and the second frequency of the second RF signal and the control of the second variable element are performed based on the second parameter acquired in the process (c). In addition, the detection of the first parameter and the second parameter in the process (c), and the process (d) and the process (e) are performed at different timings. As a result, the plasma can be more stably maintained.

In the above exemplary embodiment, the controller 2 acquires the first parameter and the second parameter detected at the same timing in the process (c). As a result, a time during which each signal is detected can be shortened, and the detection and the control of each signal can be performed many times in a shorter time. As a result, each signal can be controlled at a higher speed, and the plasma can be maintained more stably.

In the above exemplary embodiment, the controller 2 performs the process (d) and the process (e) at different timings. As a result, it is possible to avoid an excessive change in the plasma accompanying the control of the two RF signals, and it is possible to stably maintain the plasma.

In addition, the plasma processing apparatus 1 according to the above exemplary embodiment further includes the DC signal generator 310 and the VI sensor 315. The DC signal generator 310 is coupled to the member included in the plasma processing chamber 10 and generates a signal of a frequency lower than the first frequency and the second frequency. The VI sensor 315 detects the third parameter associated with the signal supplied to the member included in the plasma processing chamber 10. In the process (c), the controller 2 acquires the third parameter detected by the third sensor. In addition, the controller 2 performs the process (f) of controlling the state of the signal including the magnitude of the voltage of the signal supplied from the DC signal generator 310 to the member included in the plasma processing chamber 10 based on the third parameter acquired in the process (c). The process (f) is performed at a timing different from that of the detection of the first parameter, the second parameter, and the third parameter in the process (c). As a result, the plasma can be more stably maintained.

In the above exemplary embodiment, the controller 2 acquires the first parameter, the second parameter, and the third parameter detected at the same timing in the process (c). As a result, a time during which each signal is detected can be shortened, and the detection and the control of each signal can be performed many times in a shorter time. As a result, each signal can be controlled at a higher speed, and the plasma can be maintained more stably.

In the above exemplary embodiment, the controller 2 performs the process (d), the process (e), and the process (f) at different timings. As a result, it is possible to avoid an excessive change in the plasma accompanying the control of the plurality of signals, and to stably maintain the plasma.

The plasma processing apparatus 1 according to the above exemplary embodiment further includes the combiner 301, the amplifier 302, the filter 303-1, and the filter 303-2. The combiner 301 is coupled to the output terminal of the first RF generator 300-1 and the output terminal of the second RF generator 300-2, and combines the first RF signal output from the first RF generator 300-1 and the second RF signal output from the second RF generator 300-2. The amplifier 302 is coupled to the output terminal of the combiner 301 and amplifies the signal combined by the combiner 301. The filter 303-1 is coupled to the output terminal of the amplifier 302 and passes the frequency component included in the first RF signal in the signal amplified by the amplifier 302 to the matching circuit 306-1. The filter 303-2 is connected to the output terminal of the amplifier 302, and passes the frequency component included in the second RF signal in the signal amplified by the amplifier 302 to the matching circuit 306-2. As a result, the number of amplifiers 302 can be reduced, and the power supply 30 can be downsized.

Furthermore, in the above exemplary embodiment, the first parameter includes information regarding the traveling wave and the reflected wave in the first RF signal, and information regarding the voltage and the current at the input terminal of the matching circuit 306-1. The second parameter also includes information regarding the traveling wave and the reflected wave in the second RF signal and information regarding the voltage and the current at the input terminal of the matching circuit 306-2. As a result, the state of the plasma generated in the plasma processing space 10s can be accurately monitored through the states of the first RF signal and the second RF signal.

In addition, the above RF control method is executed by the plasma processing apparatus 1 including the first RF generator 300-1, the matching circuit 306-1, the first sensor, the second RF generator 300-2, the matching circuit 306-2, the second sensor, and the controller 2. The first RF generator 300-1 generates the first RF signal including the signal of the first frequency. The matching circuit 306-1 includes the first variable element and is provided in the signal line through which the first RF signal generated by the first RF generator 300-1 and supplied to the member included in the plasma processing apparatus 1 propagates. The first sensor detects the plurality of first parameters associated with the first RF signal in the signal line between the first RF generator 300-1 and the matching circuit 306-1, through which the first RF signal propagates. The second RF generator 300-2 generates the second RF signal including the signal of the second frequency different from the first frequency. The matching circuit 306-2 includes the second variable element and is provided in the signal line through which the second RF signal generated by the second RF generator 300-2 and supplied to the member included in the plasma processing apparatus 1 propagates. The second sensor detects the plurality of second parameters associated with the second RF signal in the signal line between the second RF generator 300-2 and the matching circuit 306-2, through which the second RF signal propagates. The RF control method includes the process (c), the process (d), and the process (e). In the process (c), the first parameter and the second parameter detected by the first sensor and the second sensor are acquired. In the process (d), the control of the magnitude of the power and the first frequency of the first RF signal and the control of the first variable element are performed based on the first parameter acquired by the process (c). In the process (e), the control of the magnitude of the power and the second frequency of the second RF signal and the control of the second variable element are performed based on the second parameter acquired in the process (c). In addition, the detection of the first parameter and the second parameter in the process (c), and the process (d) and the process (e) are performed at different timings. As a result, the plasma can be more stably maintained.

In one exemplary embodiment, the controller 2 is configured to perform the process (a1) of simultaneously and repeatedly acquiring at least four first parameters at the first input terminal and/or the first output terminal of the first matching circuit 306-1. Further, the controller 2 is configured to perform the process (a2) of simultaneously and repeatedly acquiring at least four second parameters at the second input terminal and/or the second output terminal of the second matching circuit 306-2. Then, the controller 2 is configured to perform the process (b) of sequentially and repeatedly performing the first control operation and the second control operation. The first control operation sequentially performs tuning of a power level of the first RF signal in the first RF generator 300-1, tuning of the frequency of the first RF signal in the first RF generator 300-1, and tuning of the first variable element in the first matching circuit 306-1 based on at least four first parameters simultaneously acquired in the process (a1). The second control operation sequentially performs tuning of the power level of the second RF signal in the second RF generator 300-2, tuning of the frequency of the second RF signal in the second RF generator 300-2, and tuning of the second variable element in the second matching circuit 306-2 based on at least four second parameters simultaneously acquired in the process (a2).

In one exemplary embodiment, the plasma processing apparatus 1 further includes the voltage pulse generator 310 and the third sensor 315. The voltage pulse generator 310 has the third output terminal, and is configured to generate the sequence of the plurality of voltage pulses. The third output terminal is coupled to the bias electrode in the substrate support 11 or the member in the plasma processing chamber 10. In one exemplary embodiment, the member in the plasma processing chamber 10 is a conductive member such as the side wall of the plasma processing chamber 10, the Faraday shield, or the like. In one exemplary embodiment, the sequence of the plurality of voltage pulses includes a sequence of voltage pulses having a first voltage level during a first state of a repetition period and a second voltage level during a second state of the repetition period. In one exemplary embodiment, an absolute value of the first voltage level is greater than an absolute value of the second voltage level. In one exemplary embodiment, the first voltage level has a negative polarity. In one exemplary embodiment, the second voltage level is a zero voltage level. In one exemplary embodiment, the third sensor 315 is configured to detect at least one third parameter at the third output terminal of the voltage pulse generator 310. The at least one third parameter is associated with the sequence of the plurality of voltage pulses. In one exemplary embodiment, the controller 2 is configured to perform a process (a3) of repeatedly acquiring at least one third parameter. Then, the controller 2 is configured to sequentially and repeatedly perform the first control operation, the second control operation, and the third control operation in the process (b). The third control operation performs tuning of the sequence of the plurality of voltage pulses in the voltage pulse generator 310 based on at least one third parameter acquired in the process (a3). The tuning of the sequence of the plurality of voltage pulses includes tuning of the voltage level.

In one exemplary embodiment, the plasma processing apparatus 1 further includes the power supply 30, a current controller, an electromagnet unit and at least one third sensor. The current controller is coupled to the power supply 30. The electromagnet unit includes at least one electromagnet 50 coupled to the current controller and disposed so as to surround the plasma processing chamber 10. The at least one third sensor is configured to detect at least one third parameter between the current controller and the electromagnet unit and/or between the electromagnet unit and the plasma processing chamber 10. In one exemplary embodiment, the controller 2 is configured to perform the process (a3) of repeatedly acquiring at least one third parameter. Then, the controller 2 is configured to sequentially and repeatedly perform the first control operation, the second control operation, and the third control operation in the process (b). The third control operation performs tuning of a current supplied to the at least one electromagnet 50 included in the electromagnet unit based on the at least one third parameter acquired in the process (a3).

In one exemplary embodiment, the plasma processing apparatus 1 further includes a third RF generator 300-3, a third matching circuit 306-3, and a plurality of (at least two) third sensors. The third RF generator 300-3 is configured to generate a third RF signal having a third frequency. In one exemplary embodiment, the third frequency is lower than the first frequency and the second frequency. In one exemplary embodiment, the third frequency is in a range of 300 kHz to 600 kHz. The third matching circuit 306-3 includes a third variable element, and has a third input terminal and a third output terminal. The third input terminal is coupled to the third RF generator 300-3, and the third output terminal is coupled to the bias electrode in the substrate support 11. The plurality of third sensors are configured to detect at least four third parameters at the third input terminal and/or the third output terminal of the third matching circuit 306-3. The at least four third parameters are associated with the third RF signal. In one exemplary embodiment, the controller 2 is configured to perform the process (a3) of simultaneously and repeatedly acquiring at least four third parameters. Then, the controller 2 is configured to sequentially and repeatedly perform the first control operation, the second control operation, and the third control operation in the process (b). The third control operation sequentially performs tuning of a power level of the third RF signal in the third RF generator 300-3, tuning of the frequency of the third RF signal in the third RF generator 300-3, and tuning of the third variable element in the third matching circuit 306-3 based on at least four third parameters simultaneously acquired in the process (a3).

In one exemplary embodiment, the plasma processing apparatus 1 further includes the combiner 301, the amplifier 302, the first filter 303-1, the second filter 303-2, and a third filter 303-3. The combiner 301 is coupled to the first RF generator 300-1, the second RF generator 300-2, and the third RF generator 300-3. Further, the combiner 301 is configured to generate a combined RF signal including the first RF signal, the second RF signal, and the third RF signal. The amplifier 302 is configured to amplify the combined RF signal. The first filter 303-1 is coupled to the first input terminal of the first matching circuit 306-1, and is configured to pass a component of the first frequency included in the combined RF signal amplified by the amplifier 302. The second filter 303-2 is coupled to the second input terminal of the second matching circuit 306-2, and is configured to pass a component of the second frequency included in the combined RF signal amplified by the amplifier 302. The third filter is coupled to the third input terminal of the third matching circuit 306-3, and is configured to pass a component of the third frequency included in the combined RF signal amplified by the amplifier 302.

In one exemplary embodiment, the plasma processing apparatus 1 further includes a fourth RF generator 300-4, a fourth matching circuit 306-4, and a plurality of (at least two) fourth sensors. The fourth RF generator 300-4 is configured to generate a fourth RF signal having a fourth frequency. In one exemplary embodiment, the fourth frequency is different from the first frequency, the second frequency and the third frequency. The fourth matching circuit 306-4 includes a fourth variable element, and has a fourth input terminal and a fourth output terminal. The fourth input terminal is coupled to the fourth RF generator 300-4, and the fourth output terminal is coupled to the antenna 14. The plurality of fourth sensors are configured to detect at least four fourth parameters at the fourth input terminal and/or the fourth output terminal of the fourth matching circuit 306-4. The at least four fourth parameters are associated with the fourth RF signal. In one exemplary embodiment, the controller 2 is configured to perform a process (a4) of simultaneously and repeatedly acquiring at least four fourth parameters. Then, the controller 2 is configured to sequentially and repeatedly perform the first control operation, the second control operation, the third control operation, and the fourth control operation in the process (b). The fourth control operation sequentially performs tuning of a power level of the fourth RF signal in the fourth RF generator 300-4, tuning of the frequency of the fourth RF signal in the fourth RF generator 300-4, and tuning of the fourth variable element in the fourth matching circuit 306-4 based on at least four fourth parameters simultaneously acquired in the process (a4).

In one exemplary embodiment, the RF system coupled to the plasma processing apparatus 1 includes the first RF generator 300-1, the first matching circuit 306-1, at least one first sensor, the second RF generator 300-2, the second matching circuit 306-2, at least one second sensor, the third RF generator 300-3, the third matching circuit 306-3, and at least one third sensor. The first RF generator 300-1 is configured to generate the first RF signal having the first frequency. The first matching circuit 306-1 includes the first variable element, and has the first input terminal and the first output terminal. The first input terminal of the first matching circuit 306-1 is coupled to the first RF generator 300-1, and the first output terminal of the first matching circuit 306-1 is coupled to the plasma processing chamber 10. The at least one first sensor is configured to detect at least two first parameters at the first input terminal and/or the first output terminal of the first matching circuit 306-1. The at least two first parameters are associated with the first RF signal. In one exemplary embodiment, each of the at least two first parameters is selected from the group consisting of the power, the voltage, and the current for the traveling wave of the first RF signal, and the power, the voltage, and the current for the reflected wave of the first RF signal. The second RF generator 300-2 is configured to generate the second RF signal having the second frequency. The second matching circuit 306-2 includes the second variable element, and has the second input terminal and the second output terminal. The second input terminal of the second matching circuit 306-2 is coupled to the second RF generator 300-2, and the second output terminal of the second matching circuit 306-2 is coupled to the plasma processing chamber 10. The at least one second sensor is configured to detect at least two second parameters at the second input terminal and/or the second output terminal of the second matching circuit 306-2. The at least two second parameters are associated with the second RF signal. In one exemplary embodiment, each of the at least two second parameters is selected from the group consisting of the power, the voltage, and the current for the traveling wave of the second RF signal, and the power, the voltage, and the current for the reflected wave of the second RF signal, and the third RF generator 300-3 is configured to generate the third RF signal having the third frequency. The third matching circuit 306-3 includes the third variable element, and has the third input terminal and the third output terminal. The third input terminal of the third matching circuit 306-3 is coupled to the third RF generator 300-3, and the third output terminal of the third matching circuit 306-3 is coupled to the plasma processing chamber 10. The at least one third sensor is configured to detect at least two third parameters at the third input terminal and/or the third output terminal of the third matching circuit 306-3. The at least two third parameters are associated with the third RF signal. In one exemplary embodiment, each of the at least two third parameters is selected from the group consisting of the power, the voltage, and the current for the traveling wave of the third RF signal, and the power, the voltage, and the current for the reflected wave of the third RF signal. In one exemplary embodiment, the controller 2 is configured to perform the process (a1) of simultaneously and repeatedly acquiring at least two first parameters at the first input terminal and/or the first output terminal of the first matching circuit 306-1. The controller 2 is configured to perform the process (a2) of simultaneously and repeatedly acquiring at least two second parameters at the second input terminal and/or the second output terminal of the second matching circuit 306-2. The controller 2 is configured to perform the process (a3) of simultaneously and repeatedly acquiring at least two third parameters at the third input terminal and/or the third output terminal of the third matching circuit 306-3. Then, the controller 2 is configured to perform the process (b) of sequentially and repeatedly performing the first control operation, the second control operation, and the third control operation. The first control operation sequentially performs tuning of the power level of the first RF signal in the first RF generator 300-1, tuning of the frequency of the first RF signal in the first RF generator 300-1, and tuning of the first variable element in the first matching circuit 306-1 based on at least two first parameters simultaneously acquired in the process (a1). The second control operation sequentially performs tuning of the power level of the second RF signal in the second RF generator 300-2, tuning of the frequency of the second RF signal in the second RF generator 300-2, and tuning of the second variable element in the second matching circuit 306-2 based on at least two second parameters simultaneously acquired in the process (a2). The third control operation sequentially performs tuning of the power level of the third RF signal in the third RF generator 300-3, tuning of the frequency of the third RF signal in the third RF generator 300-3, and tuning of the third variable element in the third matching circuit 306-3 based on at least two third parameters simultaneously acquired in the process (a3).

### Others

The present invention is not limited to the above exemplary embodiments, and various modifications can be made within the scope of the gist of the present invention.

For example, in the above exemplary embodiment, the directional coupler 304 is provided on a side of the filter 303, and the VI sensor 305 is provided on a side of the matching circuit 306 in the signal line of each RF signal, but the disclosed technology is not limited thereto. In another form, the VI sensor 305 may be provided on the side of the filter 303, and the directional coupler 304 may be provided on the side of the matching circuit 306 in the signal line of each RF signal.

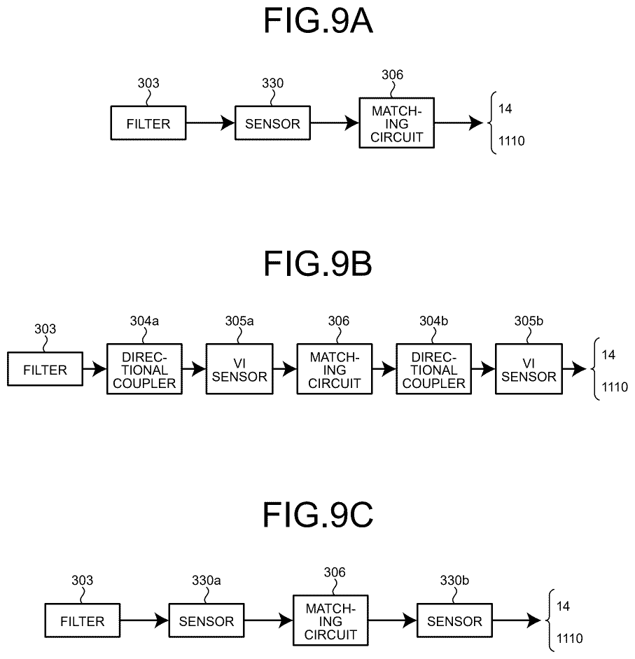

In the above exemplary embodiment, the directional coupler 304 and the VI sensor 305 are provided between the filter 303 and the matching circuit 306 in the signal line of each RF signal, but the disclosed technology is not limited thereto. As another form, for example, as illustrated in FIG. 9A, a sensor 330 including the directional coupler 304 or the VI sensor 305 may be provided between the filter 303 and the matching circuit 306. Accordingly, the number of parts can be reduced.

Alternatively, as another form, for example, as illustrated in FIG. 9B, in addition to a directional coupler 304a and a VI sensor 305a, a directional coupler 304b and a VI sensor 305b may be provided between the matching circuit 306 and a member of the plasma processing apparatus 1. As the directional coupler 304b and the VI sensor 305b are provided between the matching circuit 306 and the member (for example, the antenna 14 and the base 1110) of the plasma processing apparatus 1, a detection value that is not affected by the matching circuit 306 can be acquired. As a result, the state of the plasma can be monitored more accurately.

Alternatively, as still another form, for example, as illustrated in FIG. 9C, a sensor 330a may be provided between the filter 303 and the matching circuit 306, and a sensor 330b may be provided between the matching circuit 306 and the member (for example, the antenna 14 and the base 1110) of the plasma processing apparatus 1. As a result, it is possible to achieve both reduction in the number of parts and monitoring of the state of the plasma with higher accuracy.

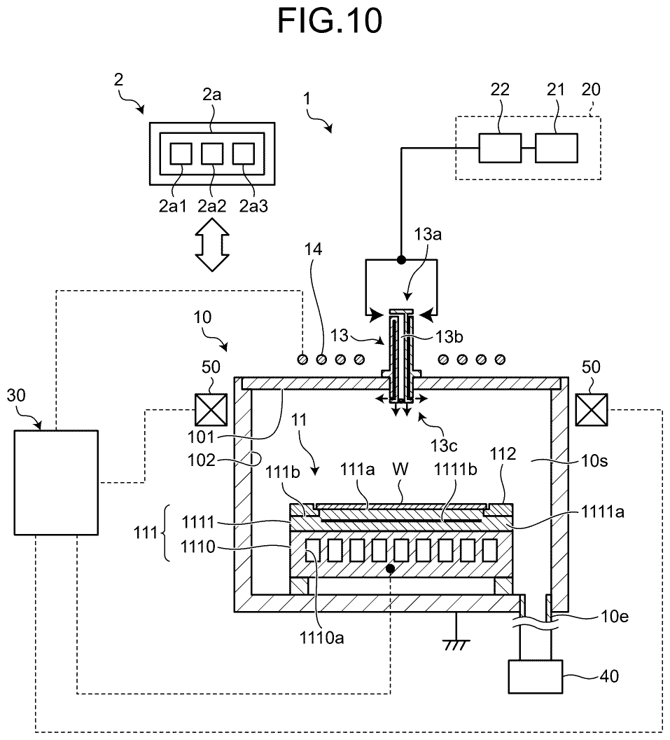

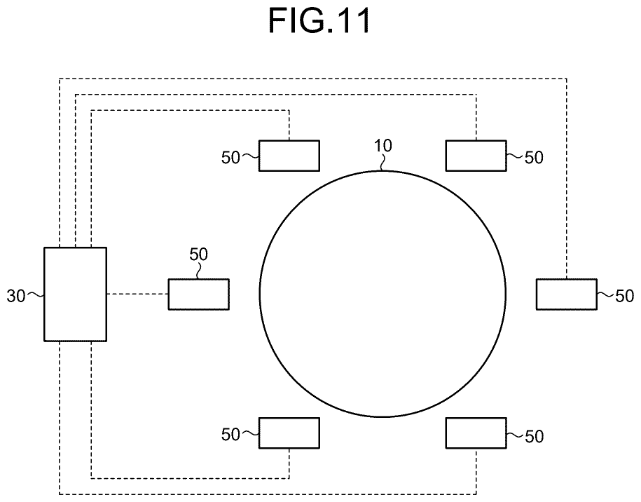

Furthermore, in the above exemplary embodiment, the DC signal generator 310 is applied to the side wall 102 of the plasma processing chamber 10, but the disclosed technology is not limited thereto. For example, as illustrated in FIGS. 10 and 11, in the plasma processing apparatus 1 having a configuration in which a plurality of electromagnets 50 are disposed around the plasma processing chamber 10, the DC signal generator 310 may individually change a state of a current supplied to each electromagnet 50. In the example of FIG. 11, six electromagnets 50 are provided in the plasma processing apparatus 1, but the number of electromagnets 50 provided in the plasma processing apparatus 1 may be more than six or less than six.

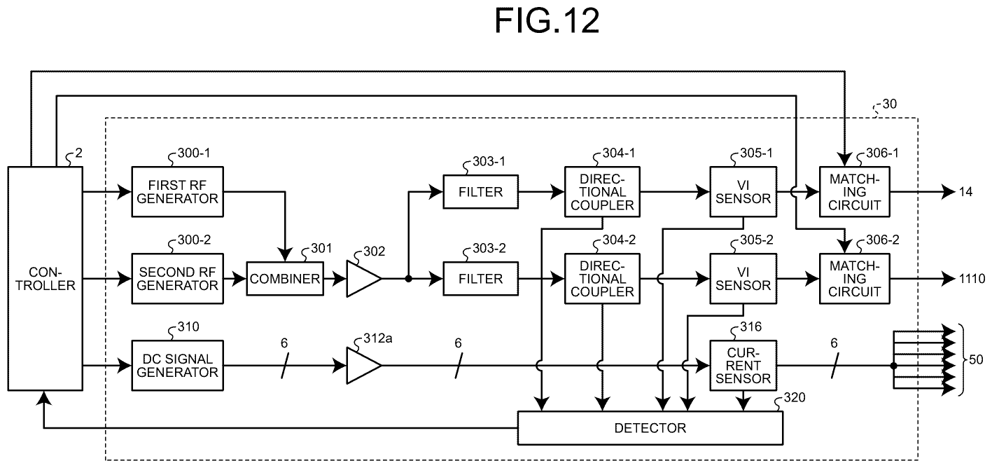

FIG. 12 is a diagram illustrating another example of the detailed configuration of the power supply 30. Except for the points described below, in FIG. 12, processing denoted with the same reference numerals as FIG. 3 is similar to the processing described in FIG. 3, and thus a description thereof is omitted.

The DC signal generator 310 illustrated in FIG. 12 generates the DC signal to be supplied to each of the plurality of electromagnets 50. The plurality of electromagnets 50 is an example of an electromagnet unit. Furthermore, the DC signal generator 310 in the example of FIG. 12 is an example of the current controller. An amplifier 312a is a voltage-current conversion amplifier provided for each DC signal. In the example of FIG. 12, six amplifiers 312a are provided. Each amplifier 312a outputs a current corresponding to the voltage of the DC signal. A current sensor 316 is provided for each DC signal and detects the state of the current supplied to each electromagnet 50. The current sensor 316 may be provided between each electromagnet 50 and the plasma processing chamber 10. In the plasma processing apparatus 1 having such a configuration, the plasma can also be more stably maintained by applying the disclosed technology.

In addition, in the above exemplary embodiment, two RF signals are supplied to the member included in the plasma processing apparatus 1, but the disclosed technology is not limited thereto. As another form, the number of RF signals supplied to the member included in the plasma processing apparatus 1 may be one or three or more.

In the above exemplary embodiment, the plasma processing apparatus 1 that performs processing on the substrate W by using inductively coupled plasma (ICP) has been described as an example of a plasma source, but the plasma source used for the processing of the substrate W is not limited thereto. Examples of the plasma source other than the inductively coupled plasma include capacitively coupled plasma (CCP), microwave-excited surface wave plasma (SWP), electron cyclotron resonance plasma (ECP), helicon wave-excited plasma (HWP), and the like. For example, a capacitively coupled plasma (CCP) apparatus includes an upper electrode and a lower electrode. The lower electrode is disposed in the substrate support, and the upper electrode is disposed above the substrate support. Then, the first to fourth matching circuits 306-1 to 306-4 are coupled to the upper electrode or the lower electrode. In one exemplary embodiment, the first matching circuit 306-1 is coupled to the upper electrode or the lower electrode, and the second matching circuit 306-2 is coupled to the lower electrode. In one exemplary embodiment, the first matching circuit 306-1 is coupled to the upper electrode, and the second matching circuit 306-2 and the third matching circuit 306-3 are coupled to the lower electrode. In one exemplary embodiment, the first to third matching circuits 306-1 to 3063 are coupled to the lower electrode. In one exemplary embodiment, the first matching circuit 306-1 and the fourth matching circuit 306-4 are coupled to the upper electrode, and the second matching circuit 306-2 and the third matching circuit 306-3 are coupled to the lower electrode. Therefore, the first to fourth matching circuits 306-1 to 306-4 are coupled to the antenna of the inductively coupled plasma apparatus, the upper electrode of the capacitively coupled plasma device, or the lower electrode (bias electrode) in the substrate support. That is, the first to fourth matching circuits 306-1 to 306-4 are coupled to the plasma processing chamber 10.

According to various aspects and exemplary embodiments of the present disclosure, plasma can be more stably maintained in processing using the plasma.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

In addition, regarding the above exemplary embodiment, the following supplementary notes are further disclosed.

### (Supplementary Note 1)

A plasma processing apparatus comprising:
a plasma processing chamber;
a substrate support disposed in the plasma processing chamber and including an electrode;
an antenna disposed above the plasma processing chamber;
a first radio frequency (RF) generator configured to generate a first RF signal having a first frequency;
a first matching circuit including a first variable element and having a first input terminal and a first output terminal, the first input terminal being coupled to the first RF generator, and the first output terminal being coupled to the antenna;
a plurality of first sensors configured to detect at least four first parameters at the first input terminal and/or the first output terminal, the at least four first parameters being associated with the first RF signal;
a second RF generator configured to generate a second RF signal having a second frequency;
a second matching circuit including a second variable element and having a second input terminal and a second output terminal, the second input terminal being coupled to the second RF generator, and the second output terminal being coupled to the electrode;
a plurality of second sensors configured to detect at least four second parameters at the second input terminal and/or the second output terminal, the at least four second parameters being associated with the second RF signal; and
a controller, wherein
the controller is configured to execute:
(a1) acquiring the at least four first parameters simultaneously and repeatedly;
(a2) acquiring the at least four second parameters simultaneously and repeatedly; and
(b) performing a first control operation and a second control operation sequentially and repeatedly,
the first control operation sequentially performs tuning of a power level of the first RF signal in the first RF generator, tuning of a frequency of the first RF signal in the first RF generator, and tuning of the first variable element in the first matching circuit based on the at least four first parameters simultaneously acquired in the (a1), and
the second control operation sequentially performs tuning of a power level of the second RF signal in the second RF generator, tuning of a frequency of the second RF signal in the second RF generator, and tuning of the second variable element in the second matching circuit based on the at least four second parameters simultaneously acquired in the (a2).

### (Supplementary Note 2)

The plasma processing apparatus according to Supplementary Note 1, including:
a voltage pulse generator having a third output terminal and configured to generate a sequence of a plurality of voltage pulses, the third output terminal being coupled to the electrode or a member in the plasma processing chamber; and
a third sensor configured to detect at least one third parameter at the third output terminal, the at least one third parameter being associated with the sequence of the plurality of voltage pulses, wherein
the controller is configured to execute (a3) acquiring the at least one third parameter repeatedly,
in the (b), the first control operation, the second control operation, and a third control operation are sequentially and repeatedly performed, and
the third control operation performs tuning of the sequence of the plurality of voltage pulses in the voltage pulse generator based on the at least one third parameter acquired in the (a3).

### (Supplementary Note 3)

The plasma processing apparatus according to Supplementary Note 1, including:
a power supply;
a current controller coupled to the power supply;
an electromagnet unit coupled to the current controller and including at least one electromagnet disposed so as to surround the plasma processing chamber; and
at least one third sensor configured to detect at least one third parameter between the current controller and the electromagnet unit and/or between the electromagnet unit and the plasma processing chamber, wherein
the controller is configured to execute (a3) acquiring the at least one third parameter repeatedly,
in the (b), the first control operation, the second control operation, and a third control operation are sequentially and repeatedly performed, and
the third control operation performs tuning of a current supplied to the electromagnet unit based on the at least one third parameter acquired in the (a3).

### (Supplementary Note 4)

The plasma processing apparatus according to any one of Supplementary Notes 1 to 3, further including:
a third RF generator configured to generate a third RF signal having a third frequency;
a third matching circuit including a third variable element and having a third input terminal and a third output terminal, the third input terminal being coupled to the third RF generator, and the third output terminal being coupled to the electrode; and
a plurality of third sensors configured to detect at least four third parameters at the third input terminal and/or the third output terminal, the at least four third parameters being associated with the third RF signal, wherein
the controller is configured to execute (a3) acquiring the at least four third parameters simultaneously and repeatedly,
in the (b), the first control operation, the second control operation, and a third control operation are sequentially and repeatedly performed, and
the third control operation sequentially performs tuning of a power level of the third RF signal in the third RF generator, tuning of a frequency of the third RF signal in the third RF generator, and tuning of the third variable element in the third matching circuit based on the at least four third parameters simultaneously acquired in the (a3).

### (Supplementary Note 5)

The plasma processing apparatus according to Supplementary Note 4, further including:
a fourth RF generator configured to generate a fourth RF signal having a fourth frequency;
a fourth matching circuit including a fourth variable element and having a fourth input terminal and a fourth output terminal, the fourth input terminal being coupled to the fourth RF generator, and the fourth output terminal being coupled to the antenna; and
a plurality of fourth sensors configured to detect at least four fourth parameters at the fourth input terminal and/or the fourth output terminal, the at least four fourth parameters being associated with the fourth RF signal, wherein
the controller is configured to execute (a4) acquiring the at least four fourth parameters simultaneously and repeatedly,
in the (b), the first control operation, the second control operation, the third control operation, and a fourth control operation are sequentially and repeatedly performed, and
the fourth control operation sequentially performs tuning of a power level of the fourth RF signal in the fourth RF generator, tuning of a frequency of the fourth RF signal in the fourth RF generator, and tuning of the fourth variable element in the fourth matching circuit based on the at least four fourth parameters simultaneously acquired in the (a4).

### (Supplementary Note 6)

The plasma processing apparatus according to any one of Supplementary Notes 1 to 5, wherein
the plurality of first sensors are configured to detect the at least four first parameters at the first input terminal, and
each of the at least four first parameters is selected from the group consisting of power, voltage, and current for a traveling wave of the first RF signal, and power, voltage, and current for a reflected wave of the first RF signal.

### (Supplementary Note 7)

The plasma processing apparatus according to any one of Supplementary Notes 1 to 6, wherein
the plurality of second sensors are configured to detect the at least four second parameters at the second input terminal, and
each of the at least four second parameters is selected from the group consisting of power, voltage, and current for a traveling wave of the second RF signal, and power, voltage, and current for a reflected wave of the second RF signal.

### (Supplementary Note 8)

The plasma processing apparatus according to Supplementary Note 4 or 5, further including:
an RF signal combiner coupled to the first RF generator, the second RF generator, and the third RF generator and configured to generate a combined RF signal including the first RF signal, the second RF signal, and the third RF signal;
an amplifier configured to amplify the combined RF signal;
a first filter coupled to the first input terminal of the first matching circuit and configured to pass a component of the first frequency included in the combined RF signal amplified by the amplifier;
a second filter coupled to the second input terminal of the first matching circuit and configured to pass a component of the second frequency included in the combined RF signal amplified by the amplifier; and
a third filter coupled to the third input terminal of the third matching circuit and configured to pass a component of the third frequency included in the combined RF signal amplified by the amplifier.

### (Supplementary Note 9)

The plasma processing apparatus according to any one of Supplementary Notes 1 to 8, wherein
each of the at least four first parameters is selected from the group consisting of power, voltage, and current for a traveling wave of the first RF signal, and power, voltage, and current for a reflected wave of the first RF signal, and
each of the at least four second parameters is selected from the group consisting of power, voltage, and current for a traveling wave of the second RF signal, and power, voltage, and current for a reflected wave of the second RF signal.

### (Supplementary Note 10)

An RF system coupled to a plasma processing apparatus, the RF system comprising:
a first RF generator configured to generate a first RF signal having a first frequency;
a first matching circuit including a first variable element and having a first input terminal and a first output terminal, the first input terminal being coupled to the first RF generator, and the first output terminal being coupled to a plasma processing chamber included in the plasma processing apparatus;
a plurality of first sensors configured to detect at least four first parameters at the first input terminal and/or the first output terminal, the at least four first parameters being associated with the first RF signal;
a second RF generator configured to generate a second RF signal having a second frequency;
a second matching circuit including a second variable element and having a second input terminal and a second output terminal, the second input terminal being coupled to the second RF generator, and the second output terminal being coupled to the plasma processing chamber;
a plurality of second sensors configured to detect at least four second parameters at the second input terminal and/or the second output terminal, the at least four second parameters being associated with the second RF signal; and
a controller, wherein
the controller is configured to execute:
(a1) acquiring the at least four first parameters simultaneously and repeatedly;
(a2) acquiring the at least four second parameters simultaneously and repeatedly; and
(b) performing a first control operation and a second control operation sequentially and repeatedly,
the first control operation sequentially performs tuning of a power level of the first RF signal in the first RF generator, tuning of a frequency of the first RF signal in the first RF generator, and tuning of the first variable element in the first matching circuit based on the at least four first parameters simultaneously acquired in the (a1), and
the second control operation sequentially performs tuning of a power level of the second RF signal in the second RF generator, tuning of a frequency of the second RF signal in the second RF generator, and tuning of the second variable element in the second matching circuit based on the at least four second parameters simultaneously acquired in the (a2).

### (Supplementary Note 11)

The RF system according to Supplementary Note 10, including:
a third RF generator configured to generate a third RF signal having a third frequency;
a third matching circuit including a third variable element and having a third input terminal and a third output terminal, the third input terminal being coupled to the third RF generator, and the third output terminal being coupled to the plasma processing chamber; and
a plurality of third sensors configured to detect at least four third parameters at the third input terminal and/or the third output terminal, the at least four third parameters being associated with the third RF signal, wherein
the controller is configured to execute (a3) acquiring the at least four third parameters simultaneously and repeatedly,
in the (b), the first control operation, the second control operation, and a third control operation are sequentially and repeatedly performed, and
the third control operation sequentially performs tuning of a power level of the third RF signal in the third RF generator, tuning of a frequency of the third RF signal in the third RF generator, and tuning of the third variable element in the third matching circuit based on the at least four third parameters simultaneously acquired in the (a3).

### (Supplementary Note 12)

The RF system according to Supplementary Note 11, further including:
an RF signal combiner coupled to the first RF generator, the second RF generator, and the third RF generator and configured to generate a combined RF signal including the first RF signal, the second RF signal, and the third RF signal;
an amplifier configured to amplify the combined RF signal;
a first filter coupled to the first input terminal of the first matching circuit and configured to pass a component of the first frequency included in the combined RF signal amplified by the amplifier;
a second filter connected to the second input terminal of the second matching circuit and configured to pass a component of the second frequency included in the combined RF signal amplified by the amplifier; and
a third filter coupled to the third input terminal of the third matching circuit and configured to pass a component of the third frequency included in the combined RF signal amplified by the amplifier.

### (Supplementary Note 13)

The RF system according to any one of Supplementary Notes 10 to 12, wherein
each of the at least four first parameters is selected from the group consisting of power, voltage, and current for a traveling wave of the first RF signal, and power, voltage, and current for a reflected wave of the first RF signal, and
each of the at least four second parameters is selected from the group consisting of power, voltage, and current for a traveling wave of the second RF signal, and power, voltage, and current for a reflected wave of the second RF signal.

### (Supplementary Note 14)

An RF system coupled to a plasma processing apparatus, the RF system comprising:
a first RF generator configured to generate a first RF signal having a first frequency;
a first matching circuit including a first variable element and having a first input terminal and a first output terminal, the first input terminal being coupled to the first RF generator, and the first output terminal being coupled to a plasma processing chamber included in the plasma processing apparatus;
at least one first sensor configured to detect at least two first parameters at the first input terminal and/or the first output terminal, the at least two first parameters being associated with the first RF signal;
a second RF generator configured to generate a second RF signal having a second frequency;
a second matching circuit including a second variable element and having a second input terminal and a second output terminal, the second input terminal being coupled to the second RF generator, and the second output terminal being coupled to the plasma processing chamber;
at least one second sensor configured to detect at least two second parameters at the second input terminal and/or the second output terminal, the at least two second parameters being associated with the second RF signal; and
a controller, wherein
the controller is configured to execute:
(a1) acquiring the at least two first parameters simultaneously and repeatedly;
(a2) acquiring the at least two second parameters simultaneously and repeatedly; and
(b) performing a first control operation and a second control operation sequentially and repeatedly,
the first control operation sequentially performs tuning of a power level of the first RF signal in the first RF generator, tuning of a frequency of the first RF signal in the first RF generator, and tuning of the first variable element in the first matching circuit based on the at least two first parameters simultaneously acquired in the (a1), and
the second control operation sequentially performs tuning of a power level of the second RF signal in the second RF generator, tuning of a frequency of the second RF signal in the second RF generator, and tuning of the second variable element in the second matching circuit based on the at least two second parameters simultaneously acquired in the (a2).

### (Supplementary Note 15)

The RF system according to Supplementary Note 14, including:
a third RF generator configured to generate a third RF signal having a third frequency;
a third matching circuit including a third variable element and having a third input terminal and a third output terminal, the third input terminal being coupled to the third RF generator, and the third output terminal being coupled to the plasma processing chamber; and
at least one third sensor configured to detect at least two third parameters at the third input terminal and/or the third output terminal, the at least two third parameters being associated with the third RF signal, wherein
the controller is configured to execute (a3) acquiring the at least two third parameters simultaneously and repeatedly,
in the (b), the first control operation, the second control operation, and a third control operation are sequentially and repeatedly performed, and
the third control operation sequentially performs tuning of a power level of the third RF signal in the third RF generator, tuning of a frequency of the third RF signal in the third RF generator, and tuning of the third variable element in the third matching circuit based on the at least two third parameters simultaneously acquired in the (a3).

### (Supplementary Note 16)

The RF system according to Supplementary Note 15, further including:
an RF signal combiner coupled to the first RF generator, the second RF generator, and the third RF generator and configured to generate a combined RF signal including the first RF signal, the second RF signal, and the third RF signal;
an amplifier configured to amplify the combined RF signal;
a first filter coupled to the first input terminal of the first matching circuit and configured to pass a component of the first frequency included in the combined RF signal amplified by the amplifier;
a second filter coupled to the second input terminal of the second matching circuit and configured to pass a component of the second frequency included in the combined RF signal amplified by the amplifier; and
a third filter coupled to the third input terminal of the third matching circuit and configured to pass a component of the third frequency included in the combined RF signal amplified by the amplifier.

### (Supplementary Note 17)

The RF system according to any one of Supplementary Notes 14 to 16, wherein
each of the at least two first parameters is selected from the group consisting of power, voltage, and current for a traveling wave of the first RF signal, and power, voltage, and current for a reflected wave of the first RF signal, and
each of the at least two second parameters is selected from the group consisting of power, voltage, and current for a traveling wave of the second RF signal, and power, voltage, and current for a reflected wave of the second RF signal.

### (Supplementary Note 18)

An RF control method executed by a plasma processing apparatus including:
a first RF generator configured to generate a first RF signal including a signal of a first frequency;
a first matching circuit including a first variable element and provided in a signal line through which the first RF signal generated by the first RF generator and supplied to a member included in the plasma processing apparatus propagates;
a first sensor configured to detect a plurality of first parameters associated with the first RF signal in a signal line between the first RF generator and the first matching circuit, through which the first RF signal propagates;
a second RF generator configured to generate a second RF signal including a signal of a second frequency different from the first frequency;
a second matching circuit including a second variable element and provided in a signal line through which the second RF signal generated by the second RF generator and supplied to a member included in the plasma processing apparatus propagates;
a second sensor configured to detect a plurality of second parameters associated with the second RF signal in a signal line between the second RF generator and the second matching circuit, through which the second RF signal propagates; and
a controller, the RF control method comprising:
c) acquiring the first parameter and the second parameter detected by the first sensor and the second sensor;
(d) performing control of a magnitude of power and the first frequency of the first RF signal and control of the first variable element based on the first parameter acquired in the (c); and
(e) performing control of a magnitude of power and the second frequency of the second RF signal and control of the second variable element based on the second parameter acquired in the (c),
wherein the detection of the first parameter and the second parameter in the (c), and the (d) and the (e) are performed at different timings.

What is claimed is:

1. A plasma processing apparatus comprising:
a plasma processing chamber;
a substrate support disposed in the plasma processing chamber and including an electrode;
an antenna disposed above the plasma processing chamber;
a first radio frequency (RF) generator configured to generate a first RF signal having a first frequency;
a first matching circuit including a first variable element and having a first input terminal and a first output terminal, the first input terminal being coupled to the first RF generator, and the first output terminal being coupled to the antenna;
a plurality of first sensors configured to detect at least four first parameters at the first input terminal and/or the first output terminal, the at least four first parameters being associated with the first RF signal;
a second RF generator configured to generate a second RF signal having a second frequency;
a second matching circuit including a second variable element and having a second input terminal and a second output terminal, the second input terminal being coupled to the second RF generator, and the second output terminal being coupled to the electrode;
a plurality of second sensors configured to detect at least four second parameters at the second input terminal and/or the second output terminal, the at least four second parameters being associated with the second RF signal; and
a controller, wherein
the controller is configured to execute:
(a1) acquiring the at least four first parameters simultaneously and repeatedly;
(a2) acquiring the at least four second parameters simultaneously and repeatedly; and
(b) performing a first control operation and a second control operation sequentially and repeatedly,
the first control operation sequentially performs tuning of a power level of the first RF signal in the first RF generator, tuning of a frequency of the first RF signal in the first RF generator, and tuning of the first variable element in the first matching circuit based on the at least four first parameters simultaneously acquired in the (a1), and
the second control operation sequentially performs tuning of a power level of the second RF signal in the second RF generator, tuning of a frequency of the second RF signal in the second RF generator, and tuning of the second variable element in the second matching circuit based on the at least four second parameters simultaneously acquired in the (a2).

2. The plasma processing apparatus according to claim 1, including:
a voltage pulse generator having a third output terminal and configured to generate a sequence of a plurality of voltage pulses, the third output terminal being coupled to the electrode or a member in the plasma processing chamber; and
a third sensor configured to detect at least one third parameter at the third output terminal, the at least one third parameter being associated with the sequence of the plurality of voltage pulses, wherein
the controller is configured to execute (a3) acquiring the at least one third parameter repeatedly,
in the (b), the first control operation, the second control operation, and a third control operation are sequentially and repeatedly performed, and
the third control operation performs tuning of the sequence of the plurality of voltage pulses in the voltage pulse generator based on the at least one third parameter acquired in the (a3).

3. The plasma processing apparatus according to claim 1, including:
a power supply;
a current controller coupled to the power supply;
an electromagnet unit coupled to the current controller and including at least one electromagnet disposed so as to surround the plasma processing chamber; and
at least one third sensor configured to detect at least one third parameter between the current controller and the electromagnet unit and/or between the electromagnet unit and the plasma processing chamber, wherein
the controller is configured to execute (a3) acquiring the at least one third parameter repeatedly,
in the (b), the first control operation, the second control operation, and a third control operation are sequentially and repeatedly performed, and
the third control operation performs tuning of a current supplied to the electromagnet unit based on the at least one third parameter acquired in the (a3).

4. The plasma processing apparatus according to claim 1, including:
a third RF generator configured to generate a third RF signal having a third frequency;
a third matching circuit including a third variable element and having a third input terminal and a third output terminal, the third input terminal being coupled to the third RF generator, and the third output terminal being coupled to the electrode; and
a plurality of third sensors configured to detect at least four third parameters at the third input terminal and/or the third output terminal, the at least four third parameters being associated with the third RF signal, wherein
the controller is configured to execute (a3) acquiring the at least four third parameters simultaneously and repeatedly,
in the (b), the first control operation,
the second control operation, and a third control operation are sequentially and repeatedly performed, and
the third control operation sequentially performs tuning of a power level of the third RF signal in the third RF generator, tuning of a frequency of the third RF signal in the third RF generator, and tuning of the third variable element in the third matching circuit based on the at least four third parameters simultaneously acquired in the (a3).

5. The plasma processing apparatus according to claim 4, further including:
a fourth RF generator configured to generate a fourth RF signal having a fourth frequency;
a fourth matching circuit including a fourth variable element and having a fourth input terminal and a fourth output terminal, the fourth input terminal being coupled to the fourth RF generator, and the fourth output terminal being coupled to the antenna; and
a plurality of fourth sensors configured to detect at least four fourth parameters at the fourth input terminal and/or the fourth output terminal, the at least four fourth parameters being associated with the fourth RF signal, wherein
the controller is configured to execute (a4) acquiring the at least four fourth parameters simultaneously and repeatedly,
in the (b), the first control operation, the second control operation, the third control operation, and a fourth control operation are sequentially and repeatedly performed, and
the fourth control operation sequentially performs tuning of a power level of the fourth RF signal in the fourth RF generator, tuning of a frequency of the fourth RF signal in the fourth RF generator, and tuning of the fourth variable element in the fourth matching circuit based on the at least four fourth parameters simultaneously acquired in the (a4).

6. The plasma processing apparatus according to claim 1, wherein
the plurality of first sensors are configured to detect the at least four first parameters at the first input terminal, and
each of the at least four first parameters is selected from the group consisting of power, voltage, and current for a traveling wave of the first RF signal, and power, voltage, and current for a reflected wave of the first RF signal.

7. The plasma processing apparatus according to claim 6, wherein
the plurality of second sensors are configured to detect the at least four second parameters at the second input terminal, and
each of the at least four second parameters is selected from the group consisting of power, voltage, and current for a traveling wave of the second RF signal, and power, voltage, and current for a reflected wave of the second RF signal.

8. The plasma processing apparatus according to claim 4, further including:
an RF signal combiner coupled to the first RF generator, the second RF generator, and the third RF generator and configured to generate a combined RF signal including the first RF signal, the second RF signal, and the third RF signal;
an amplifier configured to amplify the combined RF signal;
a first filter coupled to the first input terminal of the first matching circuit and configured to pass a component of the first frequency included in the combined RF signal amplified by the amplifier;
a second filter coupled to the second input terminal of the first matching circuit and configured to pass a component of the second frequency included in the combined RF signal amplified by the amplifier; and
a third filter coupled to the third input terminal of the third matching circuit and configured to pass a component of the third frequency included in the combined RF signal amplified by the amplifier.

9. The plasma processing apparatus according to claim 1, wherein
each of the at least four first parameters is selected from the group consisting of power, voltage, and current for a traveling wave of the first RF signal, and power, voltage, and current for a reflected wave of the first RF signal, and
each of the at least four second parameters is selected from the group consisting of power, voltage, and current for a traveling wave of the second RF signal, and power, voltage, and current for a reflected wave of the second RF signal.

10. An RF system coupled to a plasma processing apparatus, the RF system comprising:
a first RF generator configured to generate a first RF signal having a first frequency;
a first matching circuit including a first variable element and having a first input terminal and a first output terminal, the first input terminal being coupled to the first RF generator, and the first output terminal being coupled to a plasma processing chamber included in the plasma processing apparatus;
a plurality of first sensors configured to detect at least four first parameters at the first input terminal and/or the first output terminal, the at least four first parameters being associated with the first RF signal;
a second RF generator configured to generate a second RF signal having a second frequency;
a second matching circuit including a second variable element and having a second input terminal and a second output terminal, the second input terminal being coupled to the second RF generator, and the second output terminal being coupled to the plasma processing chamber;
a plurality of second sensors configured to detect at least four second parameters at the second input terminal and/or the second output terminal, the at least four second parameters being associated with the second RF signal; and
a controller, wherein
the controller is configured to execute:
(a1) acquiring the at least four first parameters simultaneously and repeatedly;
(a2) acquiring the at least four second parameters simultaneously and repeatedly; and
(b) performing a first control operation and a second control operation sequentially and repeatedly,
the first control operation sequentially performs tuning of a power level of the first RF signal in the first RF generator, tuning of a frequency of the first RF signal in the first RF generator, and tuning of the first variable element in the first matching circuit based on the at least four first parameters simultaneously acquired in the (a1), and
the second control operation sequentially performs tuning of a power level of the second RF signal in the second RF generator, tuning of a frequency of the second RF signal in the second RF generator, and tuning of the second variable element in the second matching circuit based on the at least four second parameters simultaneously acquired in the (a2).

11. The RF system according to claim 10, including:
a third RF generator configured to generate a third RF signal having a third frequency;
a third matching circuit including a third variable element and having a third input terminal and a third output terminal, the third input terminal being coupled to the third RF generator, and the third output terminal being coupled to the plasma processing chamber; and
a plurality of third sensors configured to detect at least four third parameters at the third input terminal and/or the third output terminal, the at least four third parameters being associated with the third RF signal, wherein
the controller is configured to execute (a3) acquiring the at least four third parameters simultaneously and repeatedly,
in the (b), the first control operation, the second control operation, and a third control operation are sequentially and repeatedly performed, and
the third control operation sequentially performs tuning of a power level of the third RF signal in the third RF generator, tuning of a frequency of the third RF signal in the third RF generator, and tuning of the third variable element in the third matching circuit based on the at least four third parameters simultaneously acquired in the (a3).

12. The RF system according to claim 11, further including:
an RF signal combiner coupled to the first RF generator, the second RF generator, and the third RF generator and configured to generate a combined RF signal including the first RF signal, the second RF signal, and the third RF signal;
an amplifier configured to amplify the combined RF signal;
a first filter coupled to the first input terminal of the first matching circuit and configured to pass a component of the first frequency included in the combined RF signal amplified by the amplifier;
a second filter connected to the second input terminal of the second matching circuit and configured to pass a component of the second frequency included in the combined RF signal amplified by the amplifier; and
a third filter coupled to the third input terminal of the third matching circuit and configured to pass a component of the third frequency included in the combined RF signal amplified by the amplifier.

13. The RF system according to claim 10, wherein
each of the at least four first parameters is selected from the group consisting of power, voltage, and current for a traveling wave of the first RF signal, and power, voltage, and current for a reflected wave of the first RF signal, and
each of the at least four second parameters is selected from the group consisting of power, voltage, and current for a traveling wave of the second RF signal, and power, voltage, and current for a reflected wave of the second RF signal.

14. An RF system coupled to a plasma processing apparatus, the RF system comprising:
a first RF generator configured to generate a first RF signal having a first frequency;
a first matching circuit including a first variable element and having a first input terminal and a first output terminal, the first input terminal being coupled to the first RF generator, and the first output terminal being coupled to a plasma processing chamber included in the plasma processing apparatus;
at least one first sensor configured to detect at least two first parameters at the first input terminal and/or the first output terminal, the at least two first parameters being associated with the first RF signal;
a second RF generator configured to generate a second RF signal having a second frequency;
a second matching circuit including a second variable element and having a second input terminal and a second output terminal, the second input terminal being coupled to the second RF generator, and the second output terminal being coupled to the plasma processing chamber;
at least one second sensor configured to detect at least two second parameters at the second input terminal and/or the second output terminal, the at least two second parameters being associated with the second RF signal; and
a controller, wherein
the controller is configured to execute:
(a1) acquiring the at least two first parameters simultaneously and repeatedly;
(a2) acquiring the at least two second parameters simultaneously and repeatedly; and
(b) performing a first control operation and a second control operation sequentially and repeatedly,
the first control operation sequentially performs tuning of a power level of the first RF signal in the first RF generator, tuning of a frequency of the first RF signal in the first RF generator, and tuning of the first variable element in the first matching circuit based on the at least two first parameters simultaneously acquired in the (a1), and
the second control operation sequentially performs tuning of a power level of the second RF signal in the second RF generator, tuning of a frequency of the second RF signal in the second RF generator, and tuning of the second variable element in the second matching circuit based on the at least two second parameters simultaneously acquired in the (a2).

15. The RF system according to claim 14, including:
a third RF generator configured to generate a third RF signal having a third frequency;
a third matching circuit including a third variable element and having a third input terminal and a third output terminal, the third input terminal being coupled to the third RF generator, and the third output terminal being coupled to the plasma processing chamber; and
at least one third sensor configured to detect at least two third parameters at the third input terminal and/or the third output terminal, the at least two third parameters being associated with the third RF signal, wherein
the controller is configured to execute (a3) acquiring the at least two third parameters simultaneously and repeatedly,
in the (b), the first control operation, the second control operation, and a third control operation are sequentially and repeatedly performed, and
the third control operation sequentially performs tuning of a power level of the third RF signal in the third RF generator, tuning of a frequency of the third RF signal in the third RF generator, and tuning of the third variable element in the third matching circuit based on the at least two third parameters simultaneously acquired in the (a3).

16. The RF system according to claim 15, further including:
an RF signal combiner coupled to the first RF generator, the second RF generator, and the third RF generator and configured to generate a combined RF signal including the first RF signal, the second RF signal, and the third RF signal;
an amplifier configured to amplify the combined RF signal;
a first filter coupled to the first input terminal of the first matching circuit and configured to pass a component of the first frequency included in the combined RF signal amplified by the amplifier;
a second filter coupled to the second input terminal of the second matching circuit and configured to pass a component of the second frequency included in the combined RF signal amplified by the amplifier; and
a third filter coupled to the third input terminal of the third matching circuit and configured to pass a component of the third frequency included in the combined RF signal amplified by the amplifier.

17. The RF system according to claim 14, wherein
each of the at least two first parameters is selected from the group consisting of power, voltage, and current for a traveling wave of the first RF signal, and power, voltage, and current for a reflected wave of the first RF signal, and
each of the at least two second parameters is selected from the group consisting of power, voltage, and current for a traveling wave of the second RF signal, and power, voltage, and current for a reflected wave of the second RF signal.

18. An RF control method executed by a plasma processing apparatus including:
a first RF generator configured to generate a first RF signal including a signal of a first frequency;
a first matching circuit including a first variable element and provided in a signal line through which the first RF signal generated by the first RF generator and supplied to a member included in the plasma processing apparatus propagates;
a first sensor configured to detect a plurality of first parameters associated with the first RF signal in a signal line between the first RF generator and the first matching circuit, through which the first RF signal propagates;
a second RF generator configured to generate a second RF signal including a signal of a second frequency different from the first frequency;
a second matching circuit including a second variable element and provided in a signal line through which the second RF signal generated by the second RF generator and supplied to a member included in the plasma processing apparatus propagates;
a second sensor configured to detect a plurality of second parameters associated with the second RF signal in a signal line between the second RF generator and the second matching circuit, through which the second RF signal propagates; and
a controller, the RF control method comprising:
c) acquiring the first parameter and the second parameter detected by the first sensor and the second sensor;
(d) performing control of a magnitude of power and the first frequency of the first RF signal and control of the first variable element based on the first parameter acquired in the (c); and
(e) performing control of a magnitude of power and the second frequency of the second RF signal and control of the second variable element based on the second parameter acquired in the (c),
wherein the detection of the first parameter and the second parameter in the (c), and the (d) and the (e) are performed at different timings.
